(19) United States
(12) Patent Application Publication
(10) Pub. No.: US 2023/0268410 A1
(43) Pub. Date: Aug. 24, 2023

(54) VERTICAL TUNNELING FIELD-EFFECT TRANSISTOR

(71) Applicant: Intel Corporation, Santa Clara, CA (US)

(72) Inventors: Abhishek A. Sharma, Hillsboro, OR (US); Tahir Ghani, Portland, OR (US); Anand S. Murthy, Portland, OR (US); Wilfred Gomes, Portland, OR (US); Sagar Suthram, Portland, OR (US)

(73) Assignee: Intel Corporation, Santa Clara, CA (US)

(21) Appl. No.: 17/677,909

(22) Filed: Feb. 22, 2022

(51) Int. Cl. H01L 29/423; H01L 27/088; H01L 29/786; H01L 29/66; H01L 29/04; H01L 29/78

(52) U.S. Cl. CPC H01L 29/42392; H01L 27/088; H01L 29/04; H01L 29/66742; H01L 29/7827; H01L 29/78696

(57) ABSTRACT

IC devices including vertical TFETs are disclosed. An example IC device includes a substrate, a channel region, a first region, and a second region. One of the first and second regions is a source region and another one is a drain region. The first region includes a first semiconductor material. The second region includes a second semiconductor material that may be different from the first semiconductor material. The first region and the second region are doped with opposite types of dopants. The channel region includes a third semiconductor material that may be different from the first or second semiconductor material. The channel region is between the first region and the second region. The first region is between the channel region and the substrate. In some embodiments, the first or second region is formed through layer transfer or epitaxy (e.g., graphoepitaxy, chemical epitaxy, or a combination of both).

### TECHNICAL FIELD

This disclosure relates generally to the field of semiconductor devices, and more specifically, to integrated circuit (IC) devices.

### BACKGROUND

For the past several decades, the scaling of features in ICs has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more processing capacity, however, is not without issue. The necessity to optimize the performance and energy consumption of devices becomes increasingly significant. Tunneling field-effect transistors (“tunneling FETs,” “tunnel FETs,” or “TFETs”) can be a booster for performance increase and energy consumption decrease.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a perspective view of an example IC device including a vertical TFET, according to some embodiments of the disclosure.

FIG. 1B is a cross-sectional view of the example IC device, according to some embodiments of the disclosure.

FIG. 2 is a cross-sectional view of another example IC device including a vertical TFET, according to some embodiments of the disclosure.

FIG. 3 is a cross-sectional view of yet another example IC device including a vertical TFET, according to some embodiments of the disclosure.

FIG. 4 is a cross-sectional view of yet another example IC device including a vertical TFET, according to some embodiments of the disclosure.

FIGS. 5A-5Q illustrate an example process of forming a vertical TFET through layer transfer, according to some embodiments of the disclosure.

FIGS. 6A-6C illustrate an example process of forming a vertical TFET through epitaxy, according to some embodiments of the disclosure.

FIGS. 7A-7C illustrate an example process of forming a vertical TFET through graphoepitaxy, according to some embodiments of the disclosure.

FIGS. 8A-8E illustrate an example process of forming a vertical TFET through chemoepitaxy, according to some embodiments of the disclosure.

FIG. 9 is a flowchart showing a method forming an IC device, in accordance with various embodiments.

FIG. 10 is a flowchart showing another method of forming an IC device, in accordance with various embodiments.

FIGS. 11A-11B are top views of a wafer and dies that may include one or more vertical TFETs, according to some embodiments of the disclosure.

FIG. 12 is a side, cross-sectional view of an example IC package that may include one or more IC devices having vertical TFETs, according to some embodiments of the disclosure.

FIG. 13 is a cross-sectional side view of an IC device assembly that may include components having one or more IC devices implementing vertical TFETs, according to some embodiments of the disclosure.

FIG. 14 is a block diagram of an example computing device that may include one or more components with vertical TFETs, according to some embodiments of the disclosure.

FIG. 15 is a block diagram of an example processing device that may include one or more vertical TFETs, according to some embodiments of the disclosure.

### DETAILED DESCRIPTION

### Overview

The systems, methods, and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC devices with vertical TFETs, proposed herein, it might be useful to first understand phenomena that may come into play in such structures. The following foundational information may be viewed as a basis from which the present disclosure may be properly explained. Such information is offered for purposes of explanation only and, accordingly, should not be construed in any way to limit the broad scope of the present disclosure and its potential applications.

Metal-oxide-semiconductor field-effect transistors (MOSFETs) have been widely used in ICs. The superiority of MOSFETs lies in the scalability of these devices. However, the channel length scaling of MOSFETs has resulted in substantial energy dissipation in conventional complementary metal oxide semiconductor (CMOS) technology. As transistor size continues to decrease, the power supply voltage to transistors in ICs also decreases. The decrease in power supply voltage requires the threshold voltage of the transistors to decrease. However, lower threshold voltages can be difficult to obtain in MOSFETs because, as the threshold voltage is reduced, the ratio of ON-current to OFF-current also decreases. The ON-current refers to the current through a MOSFET when a gate voltage applied is above the threshold voltage and could be as high the supply voltage, and the OFF-current refers to current through a MOSFET when no gate voltage is applied or when a gate voltage applied is below the threshold voltage. Also, as MOSFET gate length scaling continues, controlling short channel effects such as drain-induced barrier lowering (DIBL) and sub-threshold swing is imperative for improved performance. In order to continue realizing improved performance with scaling of MOSFETs transistors with reduced energy dissipation are needed.

TFETs have potential to reduce power consumption and energy dissipation. TFETs have different switching mechanism from MOSFETs, making TFET devices promising candidates for low-power electronics. In case of MOSFETs, carriers are injected thermionically over the barrier. However, in case of TFET, carriers are injected from source to channel due to gate field induced band-to-band tunneling (BTBT). In the OFF state, alignment between the conduction band of the channel and the valence band of the source is missing, which avoids carrier tunneling and maintains a very low leakage current. However, in the ON state, when the gate field is present, the channel region’s conduction band is pulled down, which allows it to align with the source region’s valence band. This alignment reduces the tunneling barrier width and height, which allows carrier tunneling from source to channel region. This enables a sharp turn-on when the bands are aligned, and therefore allows TFET devices to operate well below the sub-thermionic limits with sub-threshold swing values below 60mV/decade. Under OFF state condition, TFET has comparatively higher barrier for the minority carriers, which leads to negligible leakage current due to minority carrier injection. Leakage current in TFET devices is well below leakage current in MOSFET devices at shorter channel lengths.

Embodiments of the present disclosure relates to IC devices including vertical TFETs. An example IC device includes a substrate, a pair of a source region and a drain region, and a channel region. The pair includes a first region and a second region. The first region includes a first semiconductor material doped with a first type of dopant. The second region includes a second semiconductor material doped with a second type of dopant. The second type is opposite the first type. The first region, channel region, and second region are stacked vertical on the substrate. The channel region is between the first region and the second region. The first region is between the channel region and the substrate. Each of the first region, channel region, and second region may be a layer of a semiconductor material. In some embodiments, the semiconductor materials of the three regions are different from each other. The IC device also includes a gate. The gate facilitates application of gate bias on at least a portion of the channel region. A longitudinal axis of the gate may be orthogonal to the substrate. The gate comprises a gate insulator and a gate electrode. The gate insulator wraps around at least a portion of the channel region. The gate electrode wraps around at least a portion of the gate insulator.

To form an example IC device including a vertical TFET, a first region is formed on the substrate, a channel region is formed on the first region, and a second region is formed on the channel region. Then a gate insulator is formed to wrap around at least a portion of the channel region. The gate insulator may also wrap at least a portion of the first region, at least a portion of the second region, or both. Also, a gate electrode is formed to wrap around at least a portion of the gate insulator.

In some embodiments, the first, channel, or second region can be formed through layer transfer. The first region is formed on a growth substrate. The first region and growth substrate are bonded with the substrate with the first region contacting the substrate. Then the growth substrate is removed so that the first region is transferred from the growth substrate to the substrate. Similarly, the channel region can be transferred from a growth substrate to the first region and the second region can be transferred from a growth substrate to the channel region. A growth substrate may include the same material as the region that is formed on it so that the region can be formed on the growth substrate through homoepitaxy. An orientation of the region can be aligned with (i.e., in parallel or substantially parallel to) an orientation of the growth substrate. In an embodiment, the three growth substrates have aligned orientations so that the three regions have aligned orientations.

In other embodiments, the first, channel, or second region can be formed through layer transfer. For instance, the second region can be formed through epitaxial growth on the channel region. The second region may have a different semiconductor material from the channel region so that the epitaxial growth is heteroepitaxial growth, which may cause that the orientation of the second region is not aligned with the orientation of the channel region. In some embodiments, a guiding pattern, e.g., a topographical guiding pattern, a chemical guiding pattern, or a combination of both, can be used to guide the crystal growth of the second region along a particular direction, e.g., the orientation of the channel region. That way, the orientation of the second region can be aligned with the orientation of the channel region despite that the second region and the channel region have different materials.

The present disclosure provides TFETs with vertical configurations and methods of forming such TFETs. The TFETs can be used in IC devices to reduce power consumption of the IC devices. Compared with MOSFETS, TFETs also have better potential for improve performance as the scaling of features in IC devices continues.

IC devices as described herein, in particular IC devices with including vertical TFETs as described herein, may be used for providing electrical connectivity to one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations.

Further, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, such a collection may be referred to herein without the letters.

In the drawings, some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the manufacturing processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Furthermore, although a certain number of a given element may be illustrated in some of the drawings (e.g., a certain number of TFETS, a certain number of source regions, a certain number of drain regions, a certain number of channel regions, a certain number of gate insulators, a certain number of gate electrodes, etc.), this is simply for ease of illustration, and more, or less, than that number may be included in an IC device with a vertical TFET as described herein. Still further, various views shown in some of the drawings are intended to show relative arrangements of various elements therein. In other embodiments, various IC devices with vertical TFETs as described herein, or portions thereof, may include other elements or components that are not illustrated (e.g., transistor portions, various components that may be in electrical contact with any of the transistors, etc.). Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of IC devices with vertical TFETs as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side” to explain various features of the drawings, but these terms are simply for ease of discussion, and do not imply a desired or required orientation. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art.

For example, some descriptions may refer to a particular source or drain region or contact being either a source region/contact or a drain region/contact. However, unless specified otherwise, which region/contact of a transistor is considered to be a source region/contact and which region/contact is considered to be a drain region/contact is not important because under certain operating conditions, designations of source and drain are often interchangeable. Therefore, descriptions provided herein may use the term of a “S/D” region/contact to indicate that the region/contact can be either a source region/contact, or a drain region/contact.

In another example, if used, the terms “package” and “IC package” are synonymous, as are the terms “die” and “IC die,” the term “insulating” means “electrically insulating,” the term “conducting” means “electrically conducting,” unless otherwise specified. Although certain elements may be referred to in the singular herein, such elements may include multiple sub-elements. For example, “an electrically conductive material” may include one or more electrically conductive materials.

In another example, if used, the terms “oxide,” “carbide,” “nitride,” etc. refer to compounds containing, respectively, oxygen, carbon, nitrogen, etc., the term “high-k dielectric” refers to a material having a higher dielectric constant than silicon oxide, while the term “low-k dielectric” refers to a material having a lower dielectric constant than silicon oxide.

In yet another example, a term “interconnect” may be used to describe any element formed of an electrically conductive material for providing electrical connectivity to one or more components associated with an IC or/and between various such components. In general, the “interconnect” may refer to both conductive lines/wires (also sometimes referred to as “lines” or “metal lines” or “trenches”) and conductive vias (also sometimes referred to as “vias” or “metal vias”). In general, a term “conductive line” may be used to describe an electrically conductive element isolated by a dielectric material typically comprising an interlayer low-k dielectric that is provided within the plane of an IC chip. Such conductive lines are typically arranged in several levels, or several layers, of metallization stacks. On the other hand, the term “conductive via” may be used to describe an electrically conductive element that interconnects two or more conductive lines of different levels of a metallization stack. To that end, a via may be provided substantially perpendicularly to the plane of an IC chip or a support structure over which an IC device is provided and may interconnect two conductive lines in adjacent levels or two conductive lines in not adjacent levels. A term “metallization stack” may be used to refer to a stack of one or more interconnects for providing connectivity to different circuit components of an IC chip.

Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. The term “circuit” may be used to describe one or more passive and/or active components that are arranged to cooperate with one another to provide a desired function.

The terms “substantially,” “close,” “approximately,” “near,” and “about,” generally refer to being within +/- 20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/- 5-20% of a target value based on the context of a particular value as described herein or as known in the art. Also, the term “or” refers to an inclusive “or” and not to an exclusive “or.”

### Example Vertical TFETs

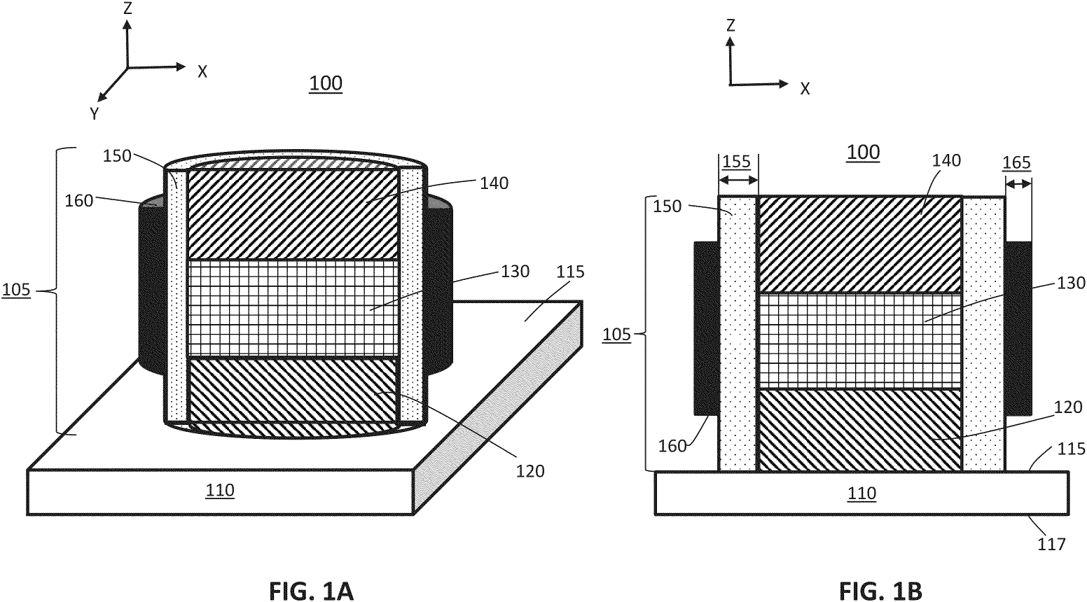

FIG. 1A is a perspective view of an example IC device 100 including a vertical TFET 105, according to some embodiments of the disclosure. FIG. 1B is a cross-sectional view of the example TFET, according to some embodiments of the disclosure. The IC device 100 also includes a substrate 110. In other embodiments, the IC device 100 may include fewer, more, or different components. FIGS. 1A and 1B also illustrate a reference coordinate system that includes an X-axis, a Y-axis, and a Z-axis, which are orthogonal to each other.

The substrate 110 may be any suitable structure with which the vertical TFET 105 can be associated. The substrate 110 has a surface 115 and a surface 117. The surface 115 is opposite the surface 117. In the embodiment of FIGS. 1A and 1B, the vertical TFET 105 is on the surface 115 of the substrate 110. In other embodiments, the vertical TFET 105 may be at least partially in the substrate 110. For instance, a portion of the vertical TFET 105, or the whole vertical TFET 105, extends from the surface 115 to the surface 117.

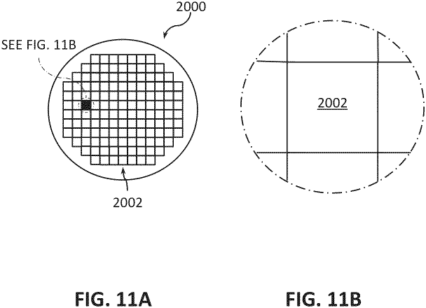

The substrate 110 may be a support structure, a die, a wafer, or a chip. In some embodiments, the substrate 110 may be a printed circuit board (PCB) substrate. In other embodiments, the substrate 110 is a semiconductor substrate, which is composed of semiconductor material systems including, for example, n-type or p-type materials systems. One or more transistors may be built on the substrate 110. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group III-V, Group II-VI, or Group IV materials. In some embodiments, the substrate may be non-crystalline. Although a few examples of materials from which the substrate 110 may be formed are described here, any material that may serve as a foundation upon which IC devices implementing vertical TFETs as described herein may be built falls within the spirit and scope of the present disclosure. In various embodiments, the substrate 110 may include any such substrate material that provides a suitable surface for forming vertical TFETs. The substrate 110 may, e.g., be the wafer 2000 of FIG. 11A, discussed below, and may be, or be included in, a die, e.g., the singulated die 2002 of FIG. 11B, discussed below.

The vertical TFET 105 includes a first region 120, a channel region 130, a second region 140, a gate insulator 150, and a gate electrode 160. The vertical TFET 105 has an orthogonal arrangement with respect to the substrate 110. The first region 120, channel region 130, and second region 140 are stacked on the substrate 110 along the Z-axis, which is perpendicular to the surface 115. As shown in FIGS. 1A and 1B, the first region 120 is over the substrate 110, particularly on the surface 115. The channel region 130 is over the first region 120. The second region 140 is over the channel region 130. The first region 120 is between the substrate 110 and the channel region 130. In some embodiments, the first region 120, channel region 130, or second region 140 is a layer of a semiconductor material. A thickness of a layer (i.e., a dimension of a layer along the Z-axis) may be in a range from 1 to 50 nm. The first region 120, channel region 130, or second region 140 may have the same or different thicknesses.

The channel region 130 is between the first region 120 and the second region 140. In some embodiments, the channel region 130 (or a combination f the first region 120, channel region 130, and second region 140) has an elongated structure, such as nanowire, fin, or nanoribbon. As shown in FIG. 1A, the channel region 130 has a longitudinal axis along the Z-axis, which is orthogonal to the substrate 110. A dimension of the channel region 130 along the Z-axis may be greater than the dimensions of the channel region 130 along the X- and Y-axes. In some embodiments (such as embodiments where the channel region 130 is a nanowire), the transverse cross-section (i.e., a cross-section in a plane perpendicular to the longitudinal axis) of the channel region 130 in a X-Y plane may be circular. In other embodiments, the semiconductor structure may have a transverse cross-section of other shapes, such as rectangular, square, triangle, trapezoid, oval, parallelogram, and so on.

The channel region 130 includes a channel material. The channel material may be composed of semiconductor material systems including, for example, n-type or p-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., AI, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nanometers and 100 nanometers, including all values and ranges therein.

For some example n-type transistor embodiments (i.e., for the embodiments where the MOSFET is a NMOS transistor and the TFET is a n-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 10¹⁵ dopant atoms per cubic centimeter (cm⁻³), and advantageously below 10¹³ cm⁻³. These materials may be amorphous or polycrystalline, e.g., having a crystal grain size between 0.5 nanometers and 100 nanometers.

For some example p-type transistor embodiments (i.e., for the embodiments where the MOSFET is a PMOS transistor and the TFET is a p-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, if the vertical TFET 105 is a thin-film transistor, the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

The first region 120 and the second region 140 constitute a pair of a source region and a drain region. In an embodiment, the first region 120 is the source region of the vertical TFET 105 and the second region 140 is the drain region of the vertical TFET 105. In another embodiment, the first region 120 is the drain region and the second region 140 is the source region. The first region 120 and the second region 140 each includes a doped semiconductor material. A doped semiconductor material is a semiconductor material into which dopants (e.g., impurities) are integrated.

The semiconductor material of the first region 120 may be different from the semiconductor material of the second region 140. In some embodiments, the semiconductor material of the first region 120 or the second region 140 is a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (AI), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

Dopants can be either p-type dopants or n-type dopants. The first region 120 and the second region 140 are doped with opposite types of dopants. For instance, the first region 120 is doped with an n-type dopant, versus the second region 140 is doped with a p-type dopant. Alternatively, the first region 120 is doped with a p-type dopant and the second region 140 is doped with an n-type dopant. Example n-type dopants include Te, S, As, tin (Sn), Si, Ga, Se, S, In, AI, Cd, chlorine (CI), iodine (I), fluorine (F), and so on. Example p-type dopants include beryllium (Be), Zn, magnesium (Mg), Sn, P, Te, lithium (Li), sodium (Na), Ga, Cd, and so on.

In some embodiments, the semiconductor material of the first region 120 is different from the semiconductor material of the second region 140, or the channel material of the channel region 130, or both. In other embodiments, the semiconductor material of the first region 120 or the second region 140 may be the same as the channel material of the channel region 130. In some embodiments, the first region 120, second region 140, and channel region 130 each include a crystalline structure and has a crystal orientation. The crystal orientation of the channel region 130 may be different from the crystal orientation of the first region 120, or the second region 140, or both. The crystal orientation of the first region 120 may be different from the crystal orientation of the second region 140.

In some embodiments, the S/D regions are highly doped, e.g., with dopant concentrations of about 1.10²¹ dopants per cubic centimeter (cm⁻³), in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the S/D regions of the vertical TFET 105 may be the regions having dopant concentration higher than in other regions, e.g., higher than a dopant concentration in the channel region 130, and, therefore, may be referred to as “highly doped” (HD) regions. The channel region 130 may include one or more semiconductor materials with doping concentrations significantly smaller than those of the S/D regions. For example, in some embodiments, the channel material of the channel region 130 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material of the vertical TFET 105 are still significantly lower than the dopant level in the S/D regions, for example below 10¹⁵ cm⁻³, or below 10¹³ cm⁻³. Depending on the context, the term “S/D terminal” may refer to a S/D region or a S/D contact or electrode of a transistor.

The channel region 130 can form a source-channel interface with the source region of the vertical TFET 105. In some embodiments, a portion of the source-channel interface is in the source region and another portion of the source-channel interface is in the channel region 130. The source-channel interface includes the type of dopants in the source region. The source-channel interface may be formed through migration of the dopants form the source region to the channel region 130. There can be a gradual change in the concentration of the dopants in the source-channel interface. For instance, the concentration of the dopants in the source-channel interface decreases along the direction from the source region to the channel region 130, i.e., there is less dopants per unit volume as it is father from the source region and closer to the channel region 130. Similarly, the channel region 130 can form a drain-channel interface with the drain region of the vertical TFET 105. The drain-channel interface includes the type of dopants in the drain region. A portion of the source-channel interface may be in the drain region and another portion of the source-channel interface may be in the channel region 130. The drain-channel interface may be formed through migration of the dopants form the drain region to the channel region 130. There can be a gradual change in the concentration of the dopants in the drain-channel interface. For instance, the concentration of the dopants in the drain-channel interface decreases along the direction from the drain region to the channel region 130, i.e., there is less dopants per unit volume as it is father from the drain region and closer to the channel region 130. In some embodiments, a length of the source-channel interface or drain-channel interface along the Z-axis is no more than 2 nm.

The gate insulator 150 separates at least a portion of the channel region 130 from the gate electrode 160 so that the channel region 130 is insulated from the gate electrode 160. In the embodiment of FIGS. 1A and 1B, the gate insulator 150 wraps around the whole first region 120, the whole channel region 130, and the whole second region 140. The first region 120, channel region 130, and second region 140 are enclosed by the gate insulator 150. In other embodiments, the gate insulator 150 may wrap around a portion of the first region 120 or a portion of the second region 140, in addition to the whole channel region 130. Alternatively, the gate insulator 150 may wrap around a portion of the channel region 130, as opposed to the whole channel region 130. The gate insulator 150 includes an electrical insulator, such as a dielectric material, hysteretic material, and so on. Example dielectric material includes oxide (e.g., Si based oxides, metal oxides, etc), high-k dielectric, and so on. Example hysteretic material include ferroelectric materials, antiferroelectric materials, etc.

In the embodiment of FIGS. 1A and 1B, the gate insulator 150 has a longitudinal axis along the Z-axis. The longitudinal axis of the gate insulator 150 is perpendicular to the surface 115 of the substrate 110. A thickness 155 of the gate insulator 150 along the X-axis, which is shown in FIG. 1B, may be in a range from 0.5 nm to 20 nm. The shape or dimensions of the gate insulator 150 can be different.

The gate electrode 160 wraps around a portion of the gate insulator 150. In some embodiments, the gate electrode 160 is provided upon the gate insulator 150 such that the gate electrode 160 does not extend beyond the gate insulator 150 in the direction along the Z-axis. In other words, a part or all of the first region 120, channel region 130, and the second region 140 is separated from the gate electrode 160 by the gate insulator 150 so that the first region 120, channel region 130, and the second region 140 do not have direct contact with the gate electrode 160. The gate electrode 160 includes an electrical conductor, such as a metal, alloy, metal-nitride, conductive oxide, conductive metal compounds, and so on. The gate electrode 160 has a longitudinal axis along the Z-axis. The longitudinal axis of the gate electrode 160 is perpendicular to the surface 115 of the substrate 110. In some embodiments, a length of the gate electrode 160 along the Z-axis is in a range from 1 nm to 50 nm. A thickness 165 of the gate electrode 160 along the X-axis, which is shown in FIG. 1B, may be in a range from 0.5 nm to 20 nm. The shape or dimensions of the gate electrode 160 can be different.

The gate electrode 160 can be coupled to a gate terminal that controls the electrostatic potential of the channel region 130. Also, additional terminals can be coupled to the first region 120 and the second region 140. In some embodiments, an opening is formed in the substrate 110 to facilitate the coupling between a terminal and the first region 120. The opening may extend from the surface 115 to the surface 117. An electrical connection (e.g., a via) may be formed in the opening to connect the first region 120 to the terminal.

The vertical TFET 105 operates based on BTBT. For BTBT to occur, an electron in the valence band of semiconductor tunnels across the band gap to the conduction band without the assistance of traps. BTBT can be triggered by applying a gate bias onto the channel region 130 through the gate electrode 160. The vertical TFET 105 can be operated by applying gate bias so that electron accumulation occurs in the channel region 130. At sufficient gate bias, BTBT occurs when the conduction band of the channel region 130 aligns with the valence band of the p-type region (i.e., the region doped with p-type dopants, e.g., the first region 120 or the second region 140). Electrons from the valence band of the p-type region tunnel into the conduction band of the channel region 130 and current can flow across the TFET. As the gate bias is reduced, the bands become misaligned and current can no longer flow. In some embodiments, the vertical TFET 105 is an n-type TFET, in which the source region is doped with p-type dopants and the drain region is doped with n-type dopants. In other embodiments, the vertical TFET 105 is a p-type TFET, in which the source region is doped with n-type dopants and the drain region is doped with p-type dopants.

In some embodiments, the vertical TFET 105 may be a thin-film transistor (TFT). A TFT is a special kind of a FET made by depositing a thin film of an active semiconductor material, as well as a dielectric layer and conductive (e.g., metallic) contacts, over a supporting layer that may be a non-conductor layer and a non-semiconductor layer. At least a portion of the active semiconductor material forms a channel region/material of the TFT. This is different from conventional, non-TFT, front-end-of line (FEOL) transistors where the semiconductor channel material of a transistor is typically a part of a semiconductor substrate, e.g., a part of a silicon wafer, or is epitaxially grown on a semiconductor substrate. Using TFTs as transistors of memory cells provides several advantages and enables unique architectures that were not possible with conventional, FEOL logic transistors. For example, advantages include substantially lower leakage in TFTs than in logic transistors and lower temperature processing used to fabricate TFTs. In context of the present disclosure, the vertical TFET 105 being a TFT advantageously allows depositing a thin-film channel material of the vertical TFET 105 in a non-planar arrangement to realize vertical transistor architecture, as will be described in greater detail below.

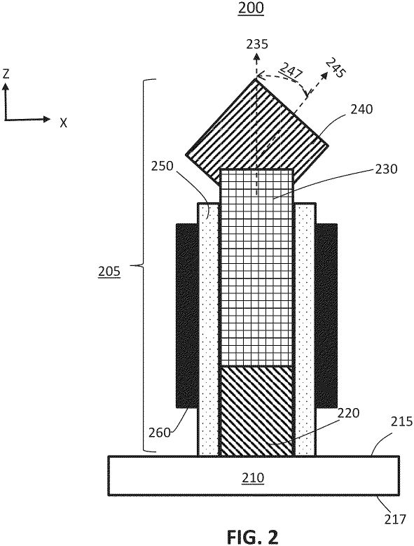

FIG. 2 is a cross-sectional view of another example device 200 including a vertical TFET 205, according to some embodiments of the disclosure. The IC device 200 also includes a substrate 210. In other embodiments, the IC device 200 may include fewer, more, or different components.

The substrate 210 may be any suitable structure with which the vertical TFET 205 can be associated. The substrate 210 has a surface 205 and another surface 207. The surface 215 is opposite the surface 217. In the embodiment of FIG. 2, the vertical TFET 205 is on the surface 215 of the substrate 210. In other embodiments, the vertical TFET 205 may be at least partially in the substrate 210. For instance, a portion of the vertical TFET 205, or the whole vertical TFET 205, extends from the surface 215 to the surface 217. The substrate 210 may be the same as or similar to the substrate 110 described above in conjunction with FIGS. 1A and 1B. The substrate 210 may, e.g., be the wafer 2000 of FIG. 21A, discussed below, and may be, or be included in, a die, e.g., the singulated die 2002 of FIG. 21B, discussed below.

The vertical TFET 205 includes a first region 220, a channel region 230, a second region 240, a gate insulator 250, and a gate electrode 260. The vertical TFET 205 has an orthogonal arrangement with respect to the substrate 210. The first region 220, channel region 230, and second region 240 are stacked on the substrate 210 along the Z-axis, which is perpendicular to the surface 215. As shown in FIG. 2, the first region 220 is over the substrate 210, particularly on the surface 215. The channel region 230 is over the first region 220. The second region 240 is over the channel region 230. The first region 220 is between the substrate 210 and the channel region 230. The channel region 230 is between the first region 220 and the second region 240.

The first region 220 and the second region 240 constitute a pair of a source region and a drain region. In an embodiment, the first region 220 is the source region of the vertical TFET 205 and the second region 240 is the drain region of the vertical TFET 205. In another embodiment, the first region 220 is the drain region and the second region 240 is the source region. The first region 220 and the second region 240 each includes a doped semiconductor material. A doped semiconductor material is a semiconductor material into which dopants (e.g., impurities) are integrated. Dopants can be either p-type dopants or n-type dopants. The first region 220 and the second region 240 are doped with opposite types of dopants. For instance, the first region 220 is doped with an n-type dopant, versus the second region 240 is doped with a p-type dopant. Alternatively, the first region 220 is doped with a p-type dopant and the second region 240 is doped with an n-type dopant.

The channel region 230 is between the first region 220 and the second region 240. The channel region 230 includes a semiconductor material. The semiconductor material of the channel region 230 may be different from the semiconductor materials of the first region 220 and the second region 240. In some embodiments, the semiconductor materials of the first region 220, second region 240, and channel region are all different from each other. In some embodiments, the channel region 230 is undoped. In other embodiments, the channel region 230 is lowly doped, e.g., with either n-type dopants or p-type dopants. The semiconductor material of the first region 220, second region 240, or channel region 230 may be one of the semiconductor materials listed above. The dopant of the first region 220, second region 240, or channel region 230 may be one of the dopants listed above.

The channel region 230 can form a source-channel interface with the source region of the vertical TFET 205. In some embodiments, a portion of the source-channel interface is in the source region and another portion of the source-channel interface is in the channel region 230. The source-channel interface includes the type of dopants in the source region. The source-channel interface may be formed through migration of the dopants form the source region to the channel region 230. There can be a gradual change in the concentration of the dopants in the source-channel interface. For instance, the concentration of the dopants in the source-channel interface decreases along the direction from the source region to the channel region 230, i.e., there is less dopants per unit volume as it is closer to the channel region 230. Similarly, the channel region 230 can form a drain-channel interface with the drain region of the vertical TFET 205. The drain-channel interface includes the type of dopants in the drain region. A portion of the drain-channel interface may be in the drain region and another portion of the drain-channel interface may be in the channel region 230. The drain-channel interface may be formed through migration of the dopants form the drain region to the channel region 230. There can be a gradual change in the concentration of the dopants in the drain-channel interface. For instance, the concentration of the dopants in the drain-channel interface decreases along the direction from the drain region to the channel region 230, i.e., there is less dopants per unit volume as it is closer to the channel region 230. In some embodiments, a length of the source-channel interface or drain-channel interface along the Z-axis is no more than 2 nm.

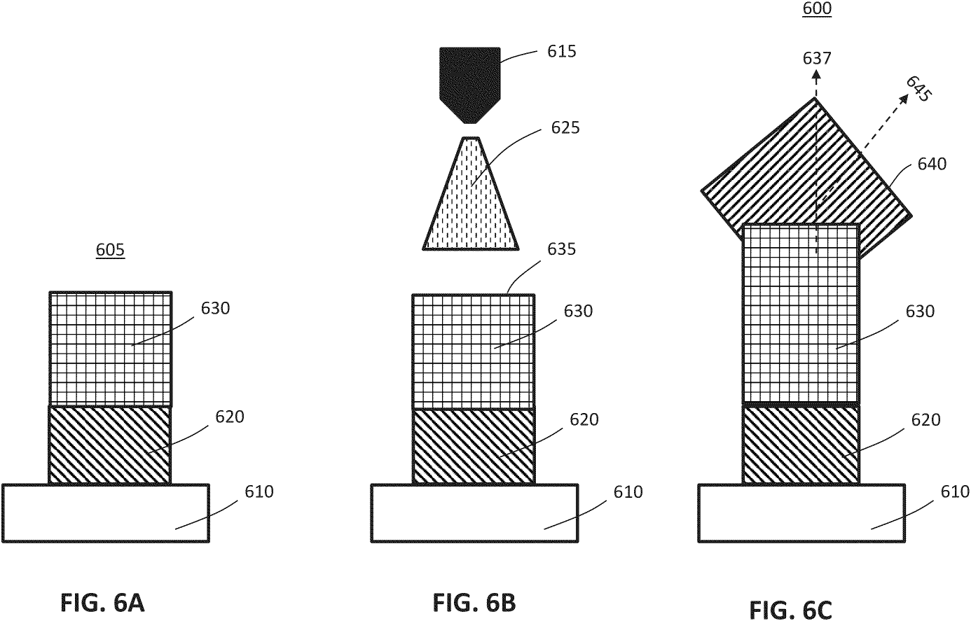

As shown in FIG. 2, the second region 240 encloses a portion of the channel region 230. The channel region 230 and the second region 240 may include crystal structures of semiconductors. A crystal structure has a crystal orientation. In the embodiment of FIG. 2, the channel region 230 has a crystal orientation 235 and the second region 240 has a crystal orientation 245. The crystal orientation 245 is at an angle 247 to the crystal orientation 235, i.e., the crystal orientation 245 is different from the crystal orientation 235. The angle 247 depends on the materials of the second region 240, the material of the channel region 230, or both. In an embodiment, the angle 247 is approximately 60 degrees. For purpose of illustration, the cross-section of the second region 240 in the X-Z plane has a shape of a parallelograms with sharp corners. In other embodiments, the cross-section of the second region 240 can have other shapes, e.g., a curved shape with round corners. In some embodiments, the second region 240 is formed through an epitaxy process, e.g., heteroepitaxy. More details regarding formation of the second region 240 is described below in conjunction with FIGS. 6A-6C.

The gate insulator 250 separates at least a portion of the channel region 230 from the gate electrode 260. In the embodiment of FIG. 2, the gate insulator 250 wraps around the first region 220 and a portion of the channel region 230, but does not wrap around any of the second region 240. The gate insulator 250 includes an electrical insulator, which may be the same as the electrical insulator of the gate insulator 150.

The gate electrode 260 wraps around a portion of the gate insulator 250. In some embodiments, the gate electrode 260 is provided upon the gate insulator 250 such that the gate electrode 260 does not extend beyond the gate insulator 250 in the direction along the Z-axis. In other words, a part or all of the first region 220, channel region 230, and the second region 240 is separated from the gate electrode 260 by the gate insulator 250 so that the first region 220, channel region 230, and the second region 240 do not have direct contact with the gate electrode 260. The gate electrode 260 includes an electrical conductor, such as one of the electrical conductors listed above. The gate electrode 260 can be coupled to a gate terminal that controls the electrostatic potential of the channel region 230.

FIG. 3 is a cross-sectional view of yet another example IC device 300 including a vertical TFET 305, according to some embodiments of the disclosure. The IC device 300 also includes a substrate 310. In other embodiments, the IC device 300 may include fewer, more, or different components.

The substrate 310 may be any suitable structure with which the vertical TFET 305 can be associated. The substrate 310 has a surface 315 and a surface 317. The surface 305 is opposite the surface 307. In the embodiment of FIG. 3, the vertical TFET 305 is on the surface 315 of the substrate 310. In other embodiments, the vertical TFET 305 may be at least partially in the substrate 310. For instance, a portion of the vertical TFET 305, or the whole vertical TFET 305, extends from the surface 315 to the surface 317. The substrate 310 may be the same as or similar to the substrate 110 described above in conjunction with FIGS. 1A and 1B. The substrate 310 may, e.g., be the wafer 2000 of FIG. 21A, discussed below, and may be, or be included in, a die, e.g., the singulated die 2002 of FIG. 21B, discussed below.

The vertical TFET 305 includes a first region 320, a channel region 330, a second region 340, a gate insulator 350, and a gate electrode 360. The vertical TFET 305 has an orthogonal arrangement with respect to the substrate 310. The first region 320, channel region 330, and second region 340 are stacked on the substrate 310 along the Z-axis, which is perpendicular to the surface 315. As shown in FIG. 3, the first region 320 is over the substrate 310, particularly on the surface 315. The channel region 330 is over the first region 320. The second region 340 is over the channel region 330. The first region 320 is between the substrate 310 and the channel region 330. The channel region 330 is between the first region 320 and the second region 340.

The first region 320 and the second region 340 constitute a pair of a source region and a drain region. In an embodiment, the first region 320 is the source region of the vertical TFET 305 and the second region 340 is the drain region of the vertical TFET 305. In another embodiment, the first region 320 is the drain region and the second region 340 is the source region. The first region 320 and the second region 340 each includes a doped semiconductor material. A doped semiconductor material is a semiconductor material into which dopants (e.g., impurities) are integrated. Dopants can be either p-type dopants or n-type dopants. The first region 320 and the second region 340 are doped with opposite types of dopants. For instance, the first region 320 is doped with an n-type dopant, versus the second region 340 is doped with a p-type dopant. Alternatively, the first region 320 is doped with a p-type dopant and the second region 340 is doped with an n-type dopant.

The channel region 330 is between the first region 320 and the second region 340. The channel region 330 includes a semiconductor material. The semiconductor material of the channel region 330 may be different from the semiconductor materials of the first region 320 and the second region 340. In some embodiments, the semiconductor materials of the first region 320, second region 340, and channel region are all different from each other. In some embodiments, the channel region 330 is undoped. In other embodiments, the channel region 330 is lowly doped, e.g., with either n-type dopants or p-type dopants. The semiconductor material of the first region 320, second region 340, or channel region may be one of the semiconductor materials listed above. The dopant of the first region 320, second region 340, or channel region may be one of the dopants listed above.

The channel region 330 can form a source-channel interface with the source region of the vertical TFET 305. In some embodiments, a portion of the source-channel interface is in the source region and another portion of the source-channel interface is in the channel region 330. The source-channel interface includes the type of dopants in the source region. The source-channel interface may be formed through migration of the dopants form the source region to the channel region 330. There can be a gradual change in the concentration of the dopants in the source-channel interface. For instance, the concentration of the dopants in the source-channel interface decreases along the direction from the source region to the channel region 330, i.e., there is less dopants per unit volume as it is closer to the channel region 330. Similarly, the channel region 330 can form a drain-channel interface with the drain region of the vertical TFET 305. The drain-channel interface includes the type of dopants in the drain region. A portion of the drain-channel interface may be in the drain region and another portion of the drain-channel interface may be in the channel region 330. The drain-channel interface may be formed through migration of the dopants form the drain region to the channel region 330. There can be a gradual change in the concentration of the dopants in the drain-channel interface. For instance, the concentration of the dopants in the drain-channel interface decreases along the direction from the drain region to the channel region 330, i.e., there is less dopants per unit volume as it is closer to the channel region 330. In some embodiments, a length of the source-channel interface or drain-channel interface along the Z-axis is no more than 2 nm.

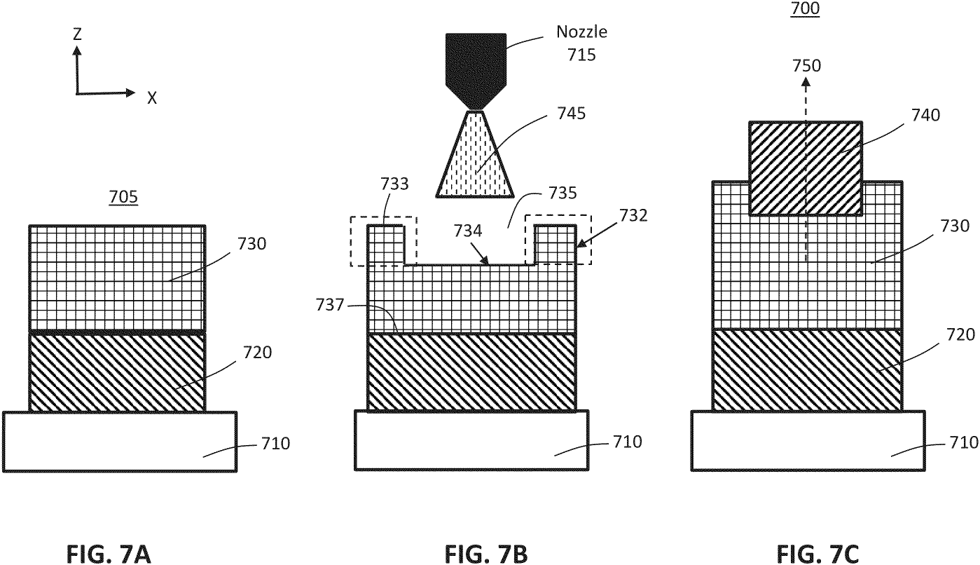

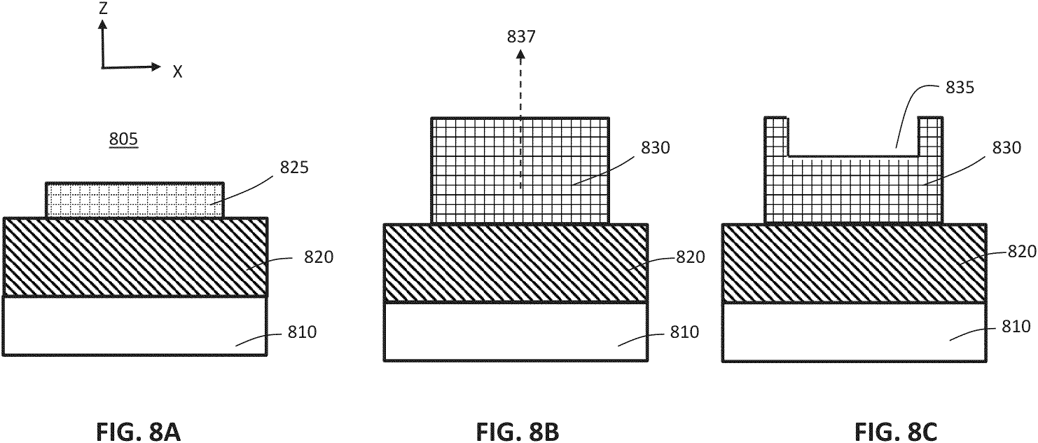

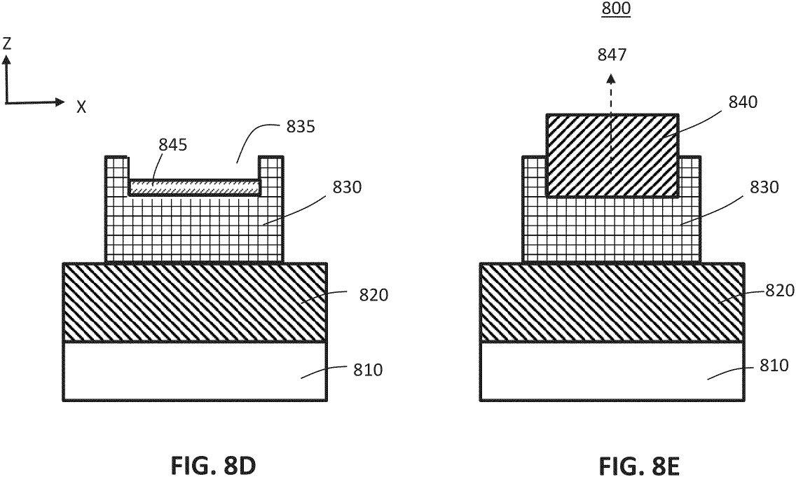

As shown in FIG. 3, a portion of the second region 340 is wrapped around by the channel region 330. The length of the second region 340 along the X-axis is shorter than the length of the channel region 330 along the X-axis. In some embodiments, the channel region 330 and the second region 340 include different semiconductor materials. The channel region 330 and the second region 340 may include crystal structures. The crystal orientations of the channel region 330 and the second region 340 may be aligned along the same direction, e.g., the Z-axis. In some embodiments, the second region 340 is formed through an epitaxy process, e.g., graphoepitaxy. More details regarding formation of the second region 340 is described below in conjunction with FIGS. 7A-7C and FIGS. 8C-8E.

The gate insulator 350 separates at least a portion of the channel region 330 from the gate electrode 360. In the embodiment of FIG. 3, the gate insulator 350 wraps around the first region 320 and a portion of the channel region 330, but does not wrap around any of the second region 340. The gate insulator 350 includes an electrical insulator, which may be the same as the electrical insulator of the gate insulator 150.

The gate electrode 360 wraps around a portion of the gate insulator 350. In some embodiments, the gate electrode 360 is provided upon the gate insulator 350 such that the gate electrode 360 does not extend beyond the gate insulator 350 in the direction along the Z-axis. In other words, a part or all of the first region 320, channel region 330, and the second region 340 is separated from the gate electrode 360 by the gate insulator 350 so that the first region 320, channel region 330, and the second region 340 do not have direct contact with the gate electrode 360. The gate electrode 360 includes an electrical conductor, such as one of the electrical conductors listed above. The gate electrode 360 can be coupled to a gate terminal that controls the electrostatic potential of the channel region 330.

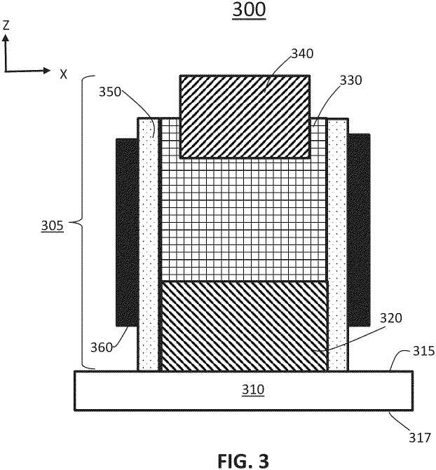

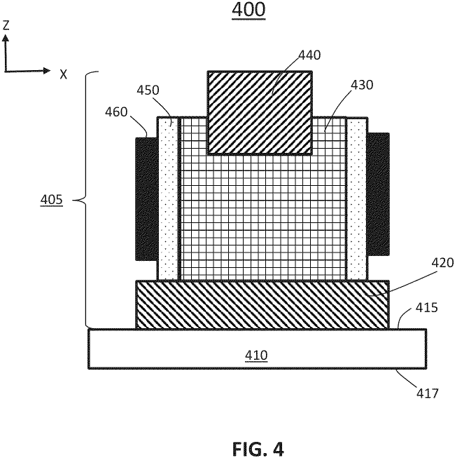

FIG. 4 is a cross-sectional view of yet another example IC device 400 including a vertical TFET 405, according to some embodiments of the disclosure. The IC device 400 also includes a substrate 410. In other embodiments, the IC device 400 may include fewer, more, or different components.

The substrate 410 may be any suitable structure with which the vertical TFET 405 can be associated. The substrate 410 has a surface 415 and a surface 417. The surface 415 is opposite the surface 417. In the embodiment of FIG. 4, the vertical TFET 405 is on the surface 415 of the substrate 410. In other embodiments, the vertical TFET 405 may be at least partially in the substrate 410. For instance, a portion of the vertical TFET 405, or the whole vertical TFET 405, extends from the surface 415 to the surface 417. The substrate 410 may be the same as or similar to the substrate 110 described above in conjunction with FIGS. 1A and 1B. The substrate 410 may, e.g., be the wafer 2000 of FIG. 21A, discussed below, and may be, or be included in, a die, e.g., the singulated die 2002 of FIG. 21B, discussed below.

The vertical TFET 405 includes a first region 420, a channel region 430, a second region 440, a gate insulator 450, and a gate electrode 460. The vertical TFET 405 has an orthogonal arrangement with respect to the substrate 410. The first region 420, channel region 430, and second region 440 are stacked on the substrate 410 along the Z-axis, which is perpendicular to the surface 415. As shown in FIG. 4, the first region 420 is over the substrate 410, particularly on the surface 415. The channel region 430 is over the first region 420. The second region 440 is over the channel region 430. The first region 420 is between the substrate 410 and the channel region 430. The channel region 430 is between the first region 420 and the second region 440.

The first region 420 and the second region 440 constitute a pair of a source region and a drain region. In an embodiment, the first region 420 is the source region of the vertical TFET 405 and the second region 440 is the drain region of the vertical TFET 405. In another embodiment, the first region 420 is the drain region and the second region 440 is the source region. The first region 420 and the second region 440 each includes a doped semiconductor material. A doped semiconductor material is a semiconductor material into which dopants (e.g., impurities) are integrated. Dopants can be either p-type dopants or n-type dopants. The first region 420 and the second region 440 are doped with opposite types of dopants. For instance, the first region 420 is doped with an n-type dopant, versus the second region 440 is doped with a p-type dopant. Alternatively, the first region 420 is doped with a p-type dopant and the second region 440 is doped with an n-type dopant.

The channel region 430 is between the first region 420 and the second region 440. The channel region 430 includes a semiconductor material. The semiconductor material of the channel region 430 may be different from the semiconductor materials of the first region 420 and the second region 440. In some embodiments, the semiconductor materials of the first region 420, second region 440, and channel region are all different from each other. In some embodiments, the channel region 430 is undoped. In other embodiments, the channel region 430 is lowly doped, e.g., with either n-type dopants or p-type dopants. The semiconductor material of the first region 420, second region 440, or channel region may be one of the semiconductor materials listed above. The dopant of the first region 420, second region 440, or channel region 430 may be one of the dopants listed above.

The channel region 430 can form a source-channel interface with the source region of the vertical TFET 405. In some embodiments, a portion of the source-channel interface is in the source region and another portion of the source-channel interface is in the channel region 430. The source-channel interface includes the type of dopants in the source region. The source-channel interface may be formed through migration of the dopants form the source region to the channel region 430. There can be a gradual change in the concentration of the dopants in the source-channel interface. For instance, the concentration of the dopants in the source-channel interface decreases along the direction from the source region to the channel region 430, i.e., there is less dopants per unit volume as it is closer to the channel region 430. Similarly, the channel region 430 can form a drain-channel interface with the drain region of the vertical TFET 405. The drain-channel interface includes the type of dopants in the drain region. A portion of the drain-channel interface may be in the drain region and another portion of the drain-channel interface may be in the channel region 430. The drain-channel interface may be formed through migration of the dopants form the drain region to the channel region 430. There can be a gradual change in the concentration of the dopants in the drain-channel interface. For instance, the concentration of the dopants in the drain-channel interface decreases along the direction from the drain region to the channel region 430, i.e., there is less dopants per unit volume as it is closer to the channel region 430. In some embodiments, a length of the source-channel interface or drain-channel interface along the Z-axis is no more than 2 nm.

As shown in FIG. 4, the length of the first region 420 along the X-axis is longer than the length of the channel region 430 along the X-axis, which is longer than the length of the second region 440 along the X-axis. Also, different from the embodiment shown in FIGS. 1A and 1B, the gate insulator 450 in FIG. 4 wraps around the channel region 430 but does not wrap around the first region 420 or the second region 440. Rather, the gate insulator 450 is over the first region 420. In some embodiments, the channel region 430 and the second region 440 can be formed through epitaxy, e.g., graphoepitaxy, chemoepitaxy, or both. More details regarding formation of the channel region 430 and the second region 440 are described below in conjunction with FIGS. 8A-8E.

The gate insulator 450 separates at least a portion of the channel region 430 from the gate electrode 460. In the embodiment of FIG. 4, the gate insulator 450 wraps around the first region 420 and a portion of the channel region 430, but does not wrap around any of the second region 440. The gate insulator 450 includes an electrical insulator, which may be the same as the electrical insulator of the gate insulator 150.

The gate electrode 460 wraps around a portion of the gate insulator 450. In some embodiments, the gate electrode 460 is provided upon the gate insulator 450 such that the gate electrode 460 does not extend beyond the gate insulator 450 in the direction along the Z-axis. In other words, a part or all of the first region 420, channel region 430, and the second region 440 is separated from the gate electrode 460 by the gate insulator 450 so that the first region 420, channel region 430, and the second region 440 do not have direct contact with the gate electrode 460. The gate electrode 460 includes an electrical conductor, such as one of the electrical conductors listed above. The gate electrode 460 can be coupled to a gate terminal that controls the electrostatic potential of the channel region 430.

### Example Processes of Forming Vertical TFETs

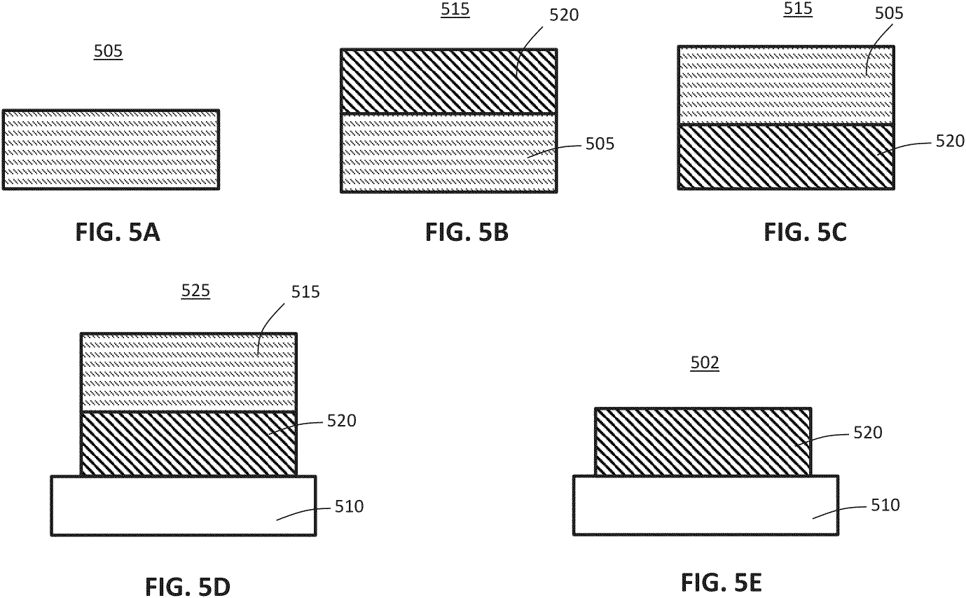

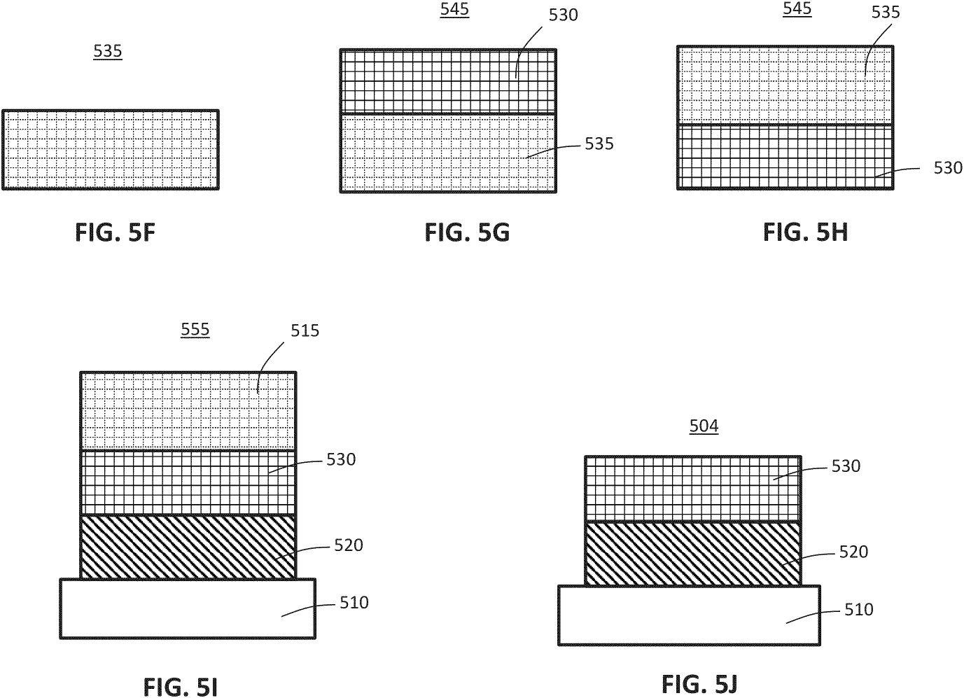

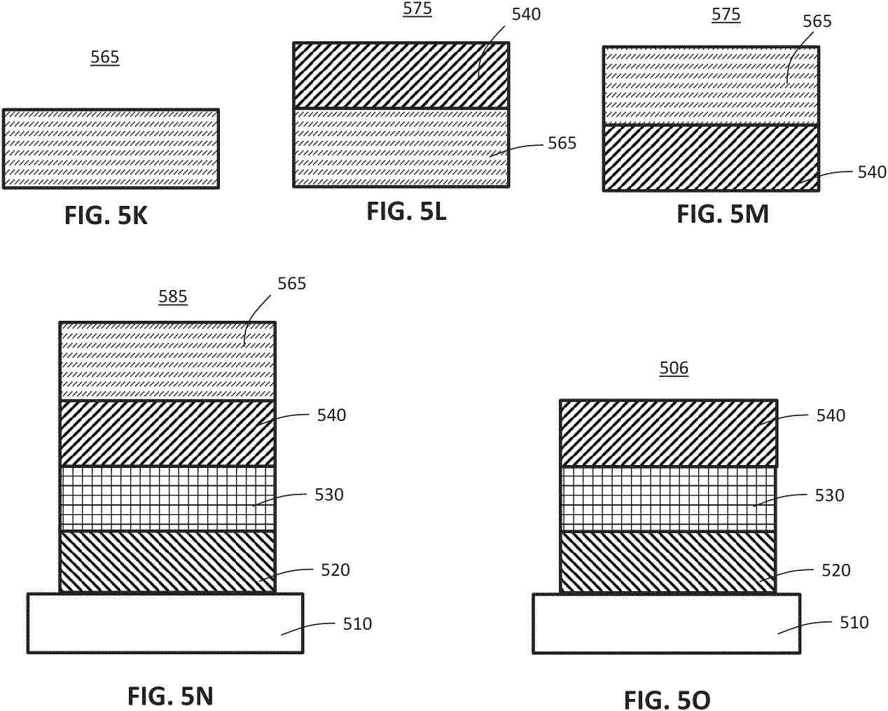

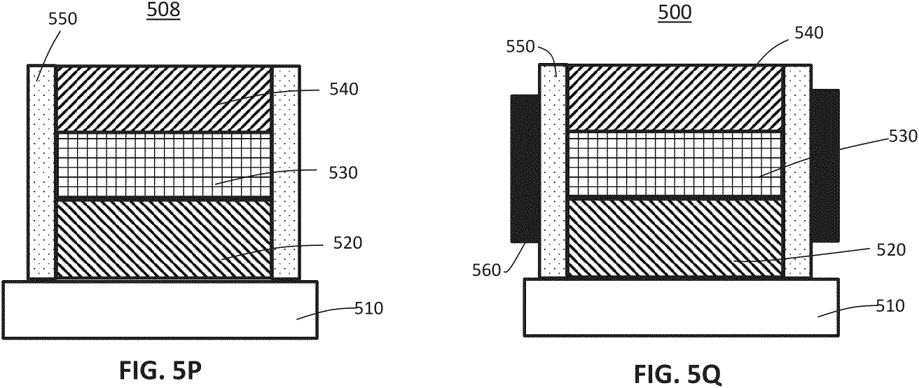

FIGS. 5A-5Q illustrate an example process of forming a vertical TFET 500 through layer transfer, according to some embodiments of the disclosure. Layer transfer includes transferring a layer (e.g., a layer of a semiconductor material) from a growth substrate (e.g., a substrate on which the layer is deposited) to a target substrate. FIG. 5A shows a growth substrate 505. The growth substrate 505 may be any suitable structure on which a semiconductor layer can be grown. The growth substrate 505 may be semiconductor substrate that includes a semiconductor material. Alternatively, the growth substrate 505 may include other materials, such as glass. The growth substrate 505 may include the same material as the substrate 110. In various embodiments, the growth substrate 505 may include any such substrate material that provides a suitable surface for forming the semiconductor layer.

In FIG. 5B, a semiconductor layer 520 is formed on the growth substrate 505, which generates a structure 515. The semiconductor layer 520 includes a semiconductor material. The semiconductor layer 520 may be an embodiment of the first region 120 in FIGS. 1A and 1B. The semiconductor layer 520 may be formed by depositing the semiconductor material onto the growth substrate 505. Various deposition techniques can be used, including, e.g., atomic layer deposition (ALD), chemical vapor deposition (CVD), physical vapor deposition (PVD), etc. Dopants (e.g., n-type dopant or p-type dopant) can be incorporated into the semiconductor material before, during, or after the formation of the semiconductor layer 520. In an embodiment, the dopant is mixed with a precursor of the semiconductor material and the mixture is sprayed onto the growth substrate 505 to form the semiconductor layer 520. In another embodiment, the dopant is incorporated into the semiconductor material after the semiconductor layer 520 is formed on the growth substrate 505. In FIG. 5C, the structure 515 is flipped over so that the semiconductor layer 520 is on the bottom and the growth substrate 505 is on the top. The step in FIG. 5C may be optional.

In FIG. 5D, the structure 515 is bonded to a substrate 510 with the semiconductor layer 520 touching the substrate 510. The substrate 510 may be an embodiment of the substrate 110 in FIGS. 1A and 1B. In some embodiments, the structure 515 and the semiconductor layer 520 are bonded together through a thermal compression process. For instance, the structure 515 is placed over the semiconductor layer 520 with the semiconductor layer 520 contacting the semiconductor layer 520 to form a structure 525. Then the structure 525 is compressed at a predetermined temperature for a predetermined duration of time to form a bonding between the semiconductor layer 520 and the substrate 510. The temperature and duration of time can be determined based on the semiconductor materials of the semiconductor layers 520 and 530.

In some embodiments, an adhesive layer (not shown in FIG. 5D) is used to facilitate the bonding. The adhesive layer may be formed on the substrate 510 or the semiconductor layer 520, e.g., through spin coating. The adhesive layer may be in a flowable state. The heating during the thermal compression can harden the adhesive layer and form a stable bond between the substrate 510 and the semiconductor layer 520. An example of the adhesive layer is a hydrogen silsesquioxane (HSQ) layer.

After the bonding process, the growth substrate 505 is removed from the structure 525. The growth substrate 505 can be removed through various techniques, such as etching, mechanical thinning, epitaxial lift-off, mechanical spalling, laser lift-off, ion cutting, and so on. As a result, a structure 502 is formed. As shown in FIG. 5E, the structure 502 includes the substrate 510 and the semiconductor layer 520. Through the steps in FIGS. 5B-5E, the semiconductor layer 520 is “transferred” from the growth substrate 505 to the substrate 510, i.e., the target substrate.

FIGS. 5F-5J shows another layer transfer process. FIG. 5F shows a growth substrate 535, which may be the same as or similar to the growth substrate 505. In FIG. 5G, a semiconductor layer 530 is formed on the growth substrate 535 and a structure 545 is generated. The semiconductor layer 530 may be formed through a process that is the same as or similar to the process of forming the semiconductor layer 520. The semiconductor layer 530 includes a semiconductor material, which may be the same as or different from the semiconductor material of the semiconductor layer 520. The semiconductor layer 530 may be an embodiment of the channel region 130 in FIGS. 1A and 1B. In FIG. 5H, the growth substrate 565 is flipped over so that the semiconductor layer 530 is on bottom and the growth substrate 535 is on top. In FIG. 5I, the growth substrate 565 is bonded to the structure 502 to form a structure 555, where the semiconductor layer 530 contacts the semiconductor layer 520. The bonding process may be the same as or similar to the bonding process described above in conjunction with FIG. 5D. In FIG. 5J, the growth substrate 535 is removed from the structure 555. Through the steps in FIGS. 5G-5J, the semiconductor layer 530 is “transferred” from the growth substrate 535 to the semiconductor layer 520, i.e., the target substrate. As a result, a structure 504 is formed. The structure 504 includes the substrate 510 and the semiconductor layers 520 and 530.

FIGS. 5K-5O shows one more layer transfer process. FIG. 5K shows a growth substrate 565, which may be the same as or similar to the growth substrate 505. In FIG. 5L, a semiconductor layer 540 is formed on the growth substrate 565 and a structure 575 is generated. The semiconductor layer 540 may be formed through a process that is the same as or similar to the process of forming the semiconductor layer 520. The semiconductor layer 540 includes a semiconductor material, which may be the same as or different from the semiconductor material of the semiconductor layer 520 or 530. The semiconductor layer 540 may be an embodiment of the second region 140 in FIGS. 1A and 1B. In FIG. 5M, the structure 575 is flipped over so that the semiconductor layer 540 is on bottom and the growth substrate 565 is on top. In FIG. 5N, the structure 575 is bonded to the structure 504 in a way such that the semiconductor layer 540 contact the semiconductor layer 530. A structure 585 is formed. The bonding process may be the same as or similar to the bonding process described above in conjunction with FIG. 5D. In FIG. 5O, the growth substrate 565 is removed from the structure 585. Through the steps in FIGS. 5L-5O, the semiconductor layer 530 is “transferred” from the growth substrate 565 to the semiconductor layer 530, i.e., the target substrate. As a result, a structure 506 is formed. The structure 506 includes the substrate 510 and the semiconductor layers 520, 530, and 540.

In FIG. 5P, an insulator 550 is formed. The insulator 550 wraps around the structure 506. In the embodiment of FIG. 5P, the insulator 550 wraps around the whole structure 506. In other embodiments, the insulator 550 wraps around a portion of the structure 506, e.g., a portion of or the whole semiconductor layer 530. The insulator 550 may be an embodiment of the gate insulator 150 in FIGS. 1A and 1B. In some embodiments, before the insulator 550 is formed, the structure 506 is changed and a new structure is formed. For instance, a portion of the semiconductor layer 520, 530, or 540 may be removed to change the shape of the structure 506. The insulator 550 is formed to wrap around at least a portion of the new structure.

In some embodiments, the insulator 550 may be deposited using a conformal deposition process, such as ALD or CVD. Conformal deposition generally refers to deposition of a certain coating on any exposed surface of a given structure. A conformal coating may, therefore, be understood as a coating that is applied to exposed surfaces of a given structure, and not, for example, just to the vertical surfaces. In some embodiments, an annealing process may be carried out on the insulator 550 to improve the quality of the insulator 550.

In FIG. 5Q, an electrode 560 is formed and the vertical TFET 500 is generated. The electrode 560 wraps around a portion of the insulator 550. In other embodiments, the electrode 560 may wrap around the whole insulator 550. The electrode 560 is separated from some or all of the semiconductor layers 520, 530, and 540 by the insulator 550. The electrode 560 may be an embodiment of the gate electrode 160 in FIGS. 1A and 1B.

The semiconductor layers 520, 530, and 530 of the vertical TFET 500 are stacked together through layer transfer processes, in which each semiconductor layer is first formed on a growth substrate and then transferred from the growth substrate to the target substrate. Such layer transfer processes can allow the integration of both lattice-matched and mismatched materials for enabling extended functionality and performance by assembling diverse materials or devices in a more compact space. The formation of a semiconductor layer (e.g., the semiconductor layer 520, 530, or 540) may be an epitaxy process, such as one of the epitaxy processes described below in conjunction with FIGS. 6A-6O. The epitaxy process includes an oriented crystal growth of the semiconductor material on the underlying substrate (e.g., the growth substrate 505, 535, or 565). Accordingly, the crystal orientations of the semiconductor layer 520, 530, or 540 can be controlled separately by using different growth substrates.

The crystal orientation of the semiconductor layer can be determined by the growth substrate. For instance, the semiconductor layer can be formed through homoepitaxial growth if the semiconductor layer and the growth substrate have the same material. With homoepitaxial growth, the crystal structure of the semiconductor layer can match (e.g., identical or substantially identical to) the crystal structure of the growth substrate and the crystal orientation of the semiconductor layer can be aligned with the crystal orientation of the growth substrate, i.e., the two crystal orientations can be the same or substantially same. In embodiments where the semiconductor layers 520, 530, and 540 have the same material, the semiconductor layers 520, 530, and 540 can be formed on identical (or substantially identical) growth substrates (or the same growth substrate if not damaged when removed) and the semiconductor layers 520, 530, and 540 can have aligned crystal orientations. Even when the semiconductor layers 520, 530, and 540 have different materials, their crystal orientations can still be aligned by using different growth substrates. For instance, growth substrates having different materials but the same crystal orientation can be used to form the semiconductor layers 520, 530, and 540. Each of the growth substate has the same material as the corresponding semiconductor layer so that the crystal orientation of the semiconductor layer will be aligned with the crystal orientation of the growth substrate. That way, the semiconductor layers 520, 530, and 540 will have aligned crystal orientations.

FIGS. 6A-6C illustrate an example process of forming a vertical TFET 600 through epitaxy, according to some embodiments of the disclosure. The epitaxy includes crystal growth of a semiconductor material on an underlying layer. The epitaxy may be a liquid phase epitaxy, a molecular beam epitaxy, a CVD epitaxy (e.g., metalorganic CVD epitaxy), etc.

FIG. 6A shows a structure 605 that includes a substrate 610 and semiconductor layers 620 and 630. The semiconductor layer 620 is between the substrate 610 and semiconductor layer 630. In some embodiments, the semiconductor layers 620 and 630 are formed through layer transfer, e.g., the layer transfer processes shown in FIGS. 5A-5J. In other embodiments, the semiconductor layer 620 or 630 may be formed through epitaxy. Each of the semiconductor layers 620 and 630 includes a semiconductor material. The semiconductor materials of the semiconductor layers 620 and 630 may be the same or different. The semiconductor layer 620 may be an embodiment of the first region 120, 220, or 320. The semiconductor layer 630 may be an embodiment of the channel region 130, 230, or 330. The semiconductor layer 630 functions as the substrate of the epitaxy process.

FIG. 6B shows depositing a semiconductor material on a surface 635 of the semiconductor layer 630. In FIG. 6B, a spraying assembly 615 sprays a fluid 625 onto the surface 635. The fluid 625 may be a gas, liquid, or supercritical fluid. The fluid 625 includes one or more precursors of the deposited semiconductor material. A precursor may include the semiconductor material or one or more chemical elements of the semiconductor material. The deposited semiconductor material may be formed through a chemical reaction between multiple precursors, chemical reaction between a precursor and a material on the surface 635, chemical reaction between a precursor and a material in the environment (e.g., a deposition chamber), or some combination thereof. The deposited semiconductor material is different from the semiconductor material of the semiconductor layer 630, i.e., the epitaxy in FIGS. 6A-6C is heteroepitaxy. The fluid 625 may also include other materials, such as an n-type or p-type dopant. The dopant in the fluid 625 is the opposite type from a dopant in the semiconductor layer 620.

In some embodiments, the spraying of the fluid 625 is performed in a chamber. The chamber may provide a controlled environment with a predetermined temperature or pressure. For example, the chamber provides a vacuum environment (e.g., a pressure of 10⁻⁸-10⁻¹² Torr) to prevent contamination. As another example, the chamber has a temperature and pressures to maintain the phase of the precursor, which may be gas, liquid, or superfluid. In some embodiments, the chamber may include plasma that facilitates the spraying of the fluid 625. For example, before the fluid 625 is sprayed onto the surface 635, the surface 635 can be treated with plasma to make the surface 635 ready for the deposition, e.g., by removing contaminants from the surface 635. As another example, the chamber can provide plasmas after the fluid 625 is sprayed onto the surface 635. The plasma facilitates solidification or crystallization of the deposited semiconductor material on the surface 635. In other embodiments, the solidification or crystallization can be done through radiation, heat, or other methods.

In FIG. 6C, a semiconductor layer 640 is formed on the surface 635. As the semiconductor material of the semiconductor layer 640 is different from the semiconductor material of the semiconductor layer 630, the semiconductor layer 640 is formed through heteroepitaxial growth on the surface 635. There can be a misalignment between the crystal structures (e.g., lattice mismatch) in the two semiconductor layers 630 and 640, which may result in a tilted growth of the semiconductor layer 640. As shown in FIG. 6C, the crystal orientation 645 of the semiconductor layer 640 is different from the crystal orientation 637 of the semiconductor layer 630.

The semiconductor layers 620, 630, and 640 constitute the semiconductor regions of the vertical TFET 600, with the semiconductor layers 620 and 640 being the source and drain regions and the semiconductor layer 630 being the channel region. Dopants can be incorporated into the crystal structures of the semiconductor layers 620, 630, and 640, e.g., through ion implantation. Even though not shown in FIGS. 6A-6C, the vertical TFET 600 may also include a gate insulator and a gate electrode, which can be formed through the process described above in conjunction with FIGS. 5P and 5Q.

FIGS. 7A-7C illustrate an example process of forming a vertical TFET through graphoepitaxy, according to some embodiments of the disclosure. The graphoepitaxy includes crystal growth guided by a topographical guiding pattern in an underlying layer. The graphoepitaxy may be a liquid phase epitaxy, a molecular beam epitaxy, a CVD epitaxy (e.g., metalorganic CVD epitaxy), etc.

FIG. 7A shows a structure 705 that includes a substrate 710 and semiconductor layers 720 and 730. The semiconductor layer 720 is between the substrate 710 and semiconductor layer 730. In some embodiments, the semiconductor layers 720 and 730 are formed through layer transfer, e.g., the layer transfer processes shown in FIGS. 5A-5J. In other embodiments, the semiconductor layer 720 or 730 may be formed through epitaxy. Each of the semiconductor layers 720 and 730 includes a semiconductor material. The semiconductor materials of the semiconductor layers 720 and 730 may be the same or different. The semiconductor layer 720 may be an embodiment of the first region 120, 220, or 320. The semiconductor layer 730 may be an embodiment of the channel region 130, 230, or 330. The semiconductor layer 730 functions as the substrate of the epitaxy process.

In FIG. 7B, an opening 735 is formed in the semiconductor layer 730. The opening 735 is formed at the surface 733 of the semiconductor layer 730. The surface 733 is opposite the surface 737, which contacts the semiconductor layer 720. As shown in FIG. 7B, a length of the opening 735 along the X-axis is shorter than the corresponding length of the semiconductor layer 730. The opening 735 is wrapped around by a portion of the semiconductor material of the semiconductor layer 730. The portion of the semiconductor material, which is enclosed in the dashed boxes in FIG. 7B, constitutes the wall 732 of the opening 735. The wall 732 has an orientation along the Z-axis. The bottom 734 of the opening 735 is surrounded by the wall 732.

The opening 735 constitutes a topographical guiding pattern for the graphoepitaxy process. The topographical guiding pattern can direct crystal growth of semiconductors. For instance, the crystallization rate of a material along the orientation of the wall 732 (i.e., the Z-axis) is higher than the crystallization rate of the material in other directions. Accordingly, the opening 735 can promote growth of epitaxial layers along the Z-axis and inhibit growth of epitaxial layers in other directions.

FIG. 7B also shows that a spraying assembly 715 sprays a fluid 745 into the opening 735 to deposit a semiconductor material on the bottom 734 of the opening 735. The fluid 745 may be a gas, liquid, or supercritical fluid. The fluid 745 includes one or more precursor of a semiconductor material. In some embodiments, the semiconductor material is different from the semiconductor material of the semiconductor layer 730 so that the graphoepitaxy is heteroepitaxy. The fluid 745 may also include a dopant, such as an n-type dopant or p-type dopant. The dopant in the fluid 745 is the opposite type from the dopant in the semiconductor layer 720. In embodiments where the semiconductor layer 730 is doped, the dopant in the fluid 745 may be the same type as the dopant in the semiconductor layer 730. The concentration of the dopant in the fluid 745 is higher than the concentration of the dopant in the semiconductor layer 730. In some embodiments, the spraying of the fluid 745 can be performed in a chamber, such as the chamber described above in conjunction with FIG. 6A.

In FIG. 7C, a semiconductor layer 740 is formed. A portion of the semiconductor layer 740 is formed in the opening 735. The rest of the semiconductor layer 740 is beyond the opening 735. The formation of the semiconductor layer 740 is guided by the opening 735 so that the semiconductor layer 740 has a crystal orientation 750 along the Z-axis.

Despite that the semiconductor layers 730 and 740 have different materials, the crystal orientation 750 of the semiconductor layer 740 can be aligned with the crystal orientation of the semiconductor layer 730 (i.e., both crystal orientations are along the Z-axis) given the topographical guiding pattern constituted by the opening 735. For instance, the crystal orientation of the semiconductor layer 730 is along the Z-axis and the opening 735 is formed based on the crystal orientation of the semiconductor layer 730. In other embodiments, the semiconductor layer 740 can have different crystal orientations, e.g., by using topographical guiding patterns that are different from the opening 735 shown in FIG. 7B.

The semiconductor layers 720, 730, and 740 constitute the semiconductor regions of the vertical TFET 700, with the semiconductor layers 720 and 740 being the source and drain regions and the semiconductor layer 730 being the channel region. Dopants can be incorporated into the crystal structures of the semiconductor layers 720, 730, and 740, e.g., through ion implantation. Even though not shown in FIGS. 7A-6C, the vertical TFET 700 may also include a gate insulator and a gate electrode, which can be formed through the process described above in conjunction with FIGS. 5P and 5Q.

Even though not shown in FIGS. 7A-7C, the semiconductor layers 720 and 730 can also be formed through graphoepitaxy. In an example, a gate insulator (e.g., the gate insulator 150) can be formed on a substrate (e.g., the substrate 110). The gate insulator can function as a topographical guiding pattern that directs the epitaxial growth of the semiconductor layers 720 and 730 along a longitudinal axis (e.g., along the Z-axis) of the gate insulator. The gate insulator can also be used to form a second region that is different from the semiconductor layer 740, e.g., the second region 140 that has the same length along the X-axis as the first region 120 and the channel region 130, through epitaxial growth. In another example, a gate insulator (e.g., the gate insulator 450) can be formed on a first region (e.g., the first region 420) and direct the epitaxial growth of a channel region (e.g., the channel region 430) on the first region.

FIGS. 8A-8E illustrate an example process of forming a vertical TFET 800 through chemoepitaxy, according to some embodiments of the disclosure. The chemoepitaxy includes crystal growth guided by a chemical guiding pattern on an underlying layer. The graphoepitaxy may be a liquid phase epitaxy, a molecular beam epitaxy, a CVD epitaxy (e.g., metalorganic CVD epitaxy), etc.

FIG. 8A shows a structure 805 that includes a substrate 810 and semiconductor layers 820. The semiconductor layer 820 is between the substrate 810 and semiconductor layer 830. In some embodiments, the semiconductor layer 820 is formed through layer transfer, e.g., the layer transfer processes shown in FIGS. 5A-5J. In other embodiments, the semiconductor layer 820 may be formed through epitaxial growth of a semiconductor material on the substrate 810. The semiconductor layer 820 may be an embodiment of the first region 120, 220, or 320.

The semiconductor layer 820 also functions as a growth substrate for a new semiconductor layer to be formed. In the embodiment of FIG. 8A, a seed layer 825 is formed on the semiconductor layer 820. The seed layer 825 can function as a chemical guiding pattern for epitaxial growth on the semiconductor layer 820 and orient the crystal growth of the new semiconductor layer. For instance, the seed layer 825 can align a crystal orientation of the new semiconductor layer with a particular direction, e.g., the crystal orientation of the semiconductor layer 820. In some embodiments, the seed layer 825 includes oriented grains of a material. The seed layer 825 may be formed by depositing a small amount of the material, heating the surface to form isolated oriented grains, and then using these grains as seeds for the deposition of an oriented layer. The seed layer 825 may have a thickness less than 1 µm.

In FIG. 8B, a semiconductor layer 830 is formed on the semiconductor layer 820. The formation of the semiconductor layer 820 is guided by the seed layer 825 so that the semiconductor layer 820 has an orientation 837 (e.g., a crystal orientation) along the Z-axis. In embodiments where the seed layer 825 includes oriented grains, the orientation 837 is aligned with the orientation of the grains in the seed layer 825. The orientation of the grains in the seed layer 825 can be aligned with an orientation of the semiconductor layer 820 so that the semiconductor layer 830 can have the same orientation as the semiconductor layer 820, even when the semiconductor layer 830 has a different material from the semiconductor layer 820.

In FIG. 8C, an opening 835 is formed in the semiconductor layer 830. The opening 835 may be the same as or similar to the opening 735 in FIG. 7B. The opening 835 can function as a topographical guiding pattern for the formation of a new layer on the semiconductor layer 830. In FIG. 8D, a seed layer 845 is formed in the opening 835. The seed layer 845 is over the bottom surface of the opening 835. Similar to the seed layer 825, the seed layer 845 can function as a chemical guiding pattern for epitaxial growth on the semiconductor layer 830 and orient the crystal growth of the new semiconductor layer. The seed layer 845 may include grains oriented along a particular direction, e.g., the Z-axis. The opening 835 and the seed layer 845 constitute a mixed guiding pattern that include both the topographical guiding pattern and the chemical guiding pattern.

In FIG. 8E, a semiconductor layer 840 is formed. A portion of the semiconductor layer 840 is formed in the opening 835. The rest of the semiconductor layer 840 is beyond the opening 835. The formation of the semiconductor layer 840 is guided by the mixed guiding pattern. Despite that the semiconductor layers 830 and 840 may have different materials, the crystal orientation 847 of the semiconductor layer 840 can be aligned with the orientation 837 of the semiconductor layer 830 (i.e., both crystal orientations are along the Z-axis) due to the mixed guiding pattern.

The semiconductor layers 820, 830, and 840 constitute the semiconductor regions of the vertical TFET 800, with the semiconductor layers 820 and 840 being the source and drain regions and the semiconductor layer 830 being the channel region. Dopants can be incorporated into the crystal structures of the semiconductor layers 820, 830, and 840, e.g., through ion implantation. Even though not shown in FIGS. 8A-6C, the vertical TFET 800 may also include a gate insulator and a gate electrode, which can be formed through the process described above in conjunction with FIGS. 5P and 5Q.

Even though not shown in FIGS. 8A-8E, the semiconductor layers 820 and 830 can also be formed through epitaxial growth directed by mixed guiding patterns. In an example, a gate insulator (e.g., the gate insulator 150) can be formed on the semiconductor layer 820. The gate insulator can function as a topographical guiding pattern that further directs the epitaxial growth of the semiconductor layer730. Similarly, the semiconductor layer 820 can be formed through epitaxial growth directed by mixed guiding patterns based on a gate insulator formed on the substrate 810 (which can function as a topographical guiding pattern) and a seed layer formed on the substrate 810 and wrapped around by the gate insulator (which functions as a chemical guiding pattern). The gate insulator can also be used to form a second region that is different from the semiconductor layer 840, e.g., the second region 140 that has the same length along the X-axis as the first region 120 and the channel region 130, through epitaxial growth.

### Example Methods of Forming IC Devices

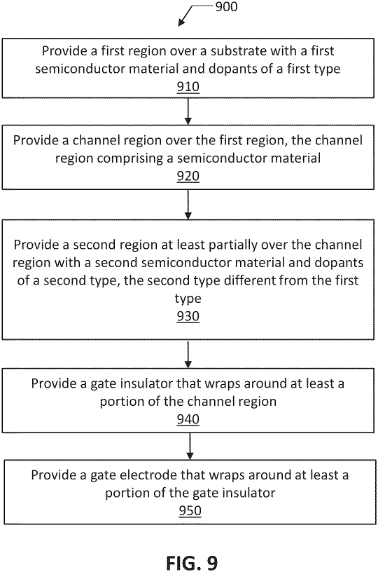

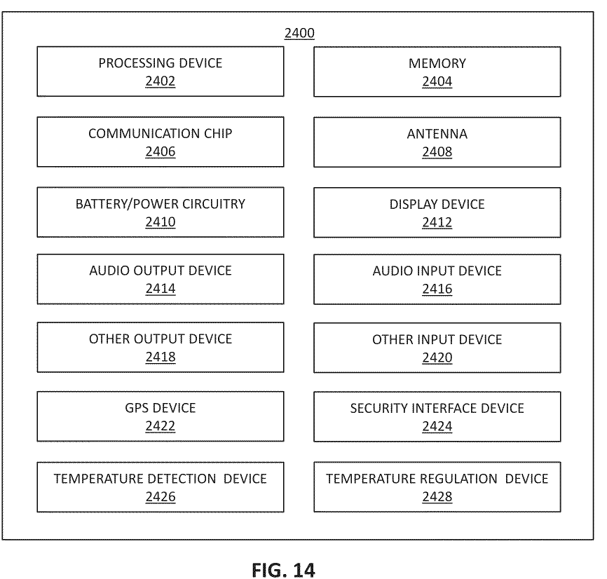

FIG. 9 is a flowchart showing a method 900 forming an IC device, in accordance with various embodiments. In some embodiments, the method 900 includes instructions that are stored in one or more non-transitory computer-readable media and are executable by a processing device, e.g., the processing device 2402 in FIG. 14. Although the method 900 is described with reference to the flowchart illustrated in FIG. 9, many other methods for forming IC devices may alternatively be used. For example, the order of execution of the steps in FIG. 9 may be changed. As another example, some of the steps may be changed, eliminated, or combined.

The method 900 includes providing (e.g., forming) 910 a first region over a substrate with a first semiconductor material and dopants of a first type. The method 900 also includes providing 920 a channel region over the first region. The channel region includes a semiconductor material. The semiconductor material may be different from the first semiconductor material. A surface of the channel region contacts a surface of the first region. The surface of the channel region may have the same size as the surface of the first region or may be smaller than the surface of the first region.

In some embodiments, the channel region is formed through layer transfer. For instance, the channel region is formed over a substrate, which generates a combined structure that includes the channel region and the substrate. The combined structure is bonded with the first region with the channel region contacting the first region. Then the substrate is removed. In other embodiments, the channel region is formed through epitaxy. For instance, a precursor of the semiconductor material is sprayed onto a surface of the first region. The channel region is formed from the precursor. The surface of the first region may be treated with a guiding material before the precursor is sprayed. An affinity of the precursor to the guiding material is stronger than the affinity of the precursor to the first semiconductor material.

The method 900 also includes providing 930 a second region at least partially over the channel region with a second semiconductor material and dopants of a second type. The second semiconductor material may be different from the first semiconductor material, the semiconductor material, or both. The second type is different from the first type. In an example, the first type is p-type and the second type is n-type. In another example, the first type is n-type and the second type is p-type. The first region and the second region constitute a pair of a source region and a drain region. The second region may be formed by layer transfer, epitaxy, or other methods. In an example, a mixture of a precursor of the second semiconductor material and dopants of the second type is sprayed onto a surface of the channel region to form the second region. In some embodiments, a guiding pattern is formed at a surface of the channel region and the second region is formed over the channel region based on the guiding pattern. The guiding pattern may include an opening that is formed in the channel region at a surface of the channel region. A precursor of the second semiconductor material (or a mixture of the precursor and dopants of the second type) is sprayed into the opening to form the second region. At least a portion of the second region is wrapped around by the channel region. The guiding pattern may further include a guiding pattern in the opening. The precursor or mixture has a stronger affinity to the guiding material than to the semiconductor material.

The method 900 also includes providing 940 a gate insulator that wraps around at least a portion of the channel region. The gate insulator may be formed with a dielectric material, such as an oxide material, a hysteretic material (e.g., a ferroelectric or an antiferroelectric material), or other materials. The method 900 further includes providing 950 a gate electrode that wraps around at least a portion of the gate insulator. The gate electrode is formed by an electrically conductive material, e.g., metal.

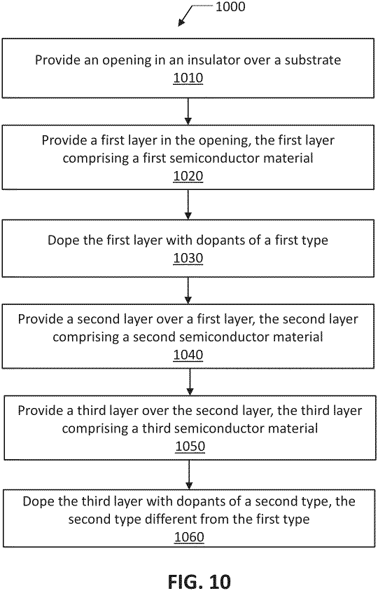

FIG. 10 is a flowchart showing another method of forming an IC device, in accordance with various embodiments. In some embodiments, the method 1000 includes instructions that are stored in one or more non-transitory computer-readable media and are executable by a processing device, e.g., the processing device 2402 in FIG. 14. Although the method 1000 is described with reference to the flowchart illustrated in FIG. 10, many other methods for providing forming IC devices may alternatively be used. For example, the order of execution of the steps in FIG. 10 may be changed. As another example, some of the steps may be changed, eliminated, or combined.

The method 1000 includes providing 1010 an opening in an insulator over a substrate. In some embodiments, the opening is formed through etching, e.g., dry etching. The opening may be a trench. The method 1000 further includes 1020 providing a first layer in the opening. The first layer includes a first semiconductor material. The method 1000 further includes doping 1030 the first layer with dopants of a first type. The first type may be p-type or n-type. In some embodiments, the first layer can be formed by spraying a precursor of the first semiconductor material into the opening. In an embodiment, a mixture of the precursor and dopants of the first type is sprayed into the opening to form the doped first layer. The first layer may be formed through graphoepitaxial growth on the substrate and the opening can function as a topographical guiding pattern for the graphoepitaxial growth.

The method 1000 further includes providing 1040 a second layer (i.e., L2) over a first layer, the second layer comprising a second semiconductor material. The second semiconductor material may be different from the first semiconductor material. In some embodiments, the second layer is formed through graphoepitaxial growth on the first layer in the opening and the opening can function as a topographical guiding pattern for the graphoepitaxial growth. The first layer and at least a portion of the second layer is wrapped around by the insulator.

The method 1000 further includes providing a third layer 1050 over the second layer. The third layer includes a third semiconductor material, which may be different from the first semiconductor material, the second semiconductor material, or both. In an embodiment, the second layer is formed through graphoepitaxial growth on the second layer in the opening in the insulator and the opening in the insulator can function as a topographical guiding pattern for the graphoepitaxial growth. In another embodiment, another opening is formed in the second layer. The third layer can be formed in the opening in the second layer, e.g., through graphoepitaxial growth. The opening in the second layer can function as a topographical guiding pattern for the graphoepitaxial growth.

The method 1000 also includes doping 1060 the third layer with dopants of a second type. The second type is different from (e.g., opposite) the first type. In an embodiment, the first type is n-type and the second type is p-type. In another example, the first type is p-type and the second type is n-type. In some embodiments, at least a portion of the third layer is wrapped around by the insulator. In some embodiments, an electrode is formed. The electrode wraps around at least a portion of the insulator.

### Example Wafer and Die

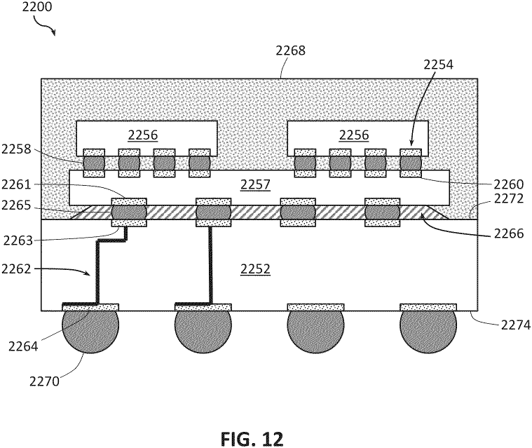

FIGS. 11A-11B are top views of a wafer 2000 and dies 2002 that may include one or more vertical TFETs, according to some embodiments of the disclosure. In some embodiments, the dies 2002 may be included in an IC package. For example, any of the dies 2002 may serve as any of the dies 2256 in an IC package 2200 shown in FIG. 12. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including one or more vertical TFETs as described herein). After the fabrication of the semiconductor product is complete (e.g., after manufacture of one or more vertical TFETs as described herein), the wafer 2000 may undergo a singulation process in which each of the dies 2002 is separated from one another to provide discrete “chips” of the semiconductor product. In particular, devices that include one or more vertical TFETs as disclosed herein may take the form of the wafer 2000 (e.g., not singulated) or the form of the die 2002 (e.g., singulated). The die 2002 may include one or more diodes, one or more transistors (e.g., one or more vertical TFETs as described herein) as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, an RF FE device, a memory device (e.g., a static random-access memory (SRAM) device), a logic device (e.g., an AND, OR, NAND, or NOR gate), or any other suitable circuit element. Multiple ones of these devices may be combined on a single die 2002.

### Example IC Package

FIG. 12 is a side, cross-sectional view of an example IC package 2200 that may include one or more IC devices having vertical TFETs, according to some embodiments of the disclosure. In some embodiments, the IC package 2200 may be a system-in-package (SiP).

As shown in FIG. 12, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 12 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 12 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

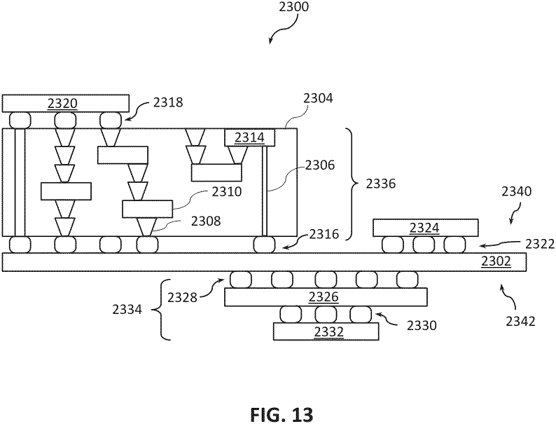

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 12 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 13.

The dies 2256 may take the form of any of the embodiments of the die 2002 discussed herein and may include any of the embodiments of an IC device having one or more vertical TFETs. In embodiments in which the IC package 2200 includes multiple dies 2256, the IC package 2200 may be referred to as a multi-chip package. Importantly, even in such embodiments of an MCP implementation of the IC package 2200, one or more vertical TFETs may be provided in a single chip, in accordance with any of the embodiments described herein. The dies 2256 may include circuitry to perform any desired functionality. For example, one or more of the dies 2256 may be ESD protection dies, including one or more vertical TFETs as described herein, one or more of the dies 2256 may be logic dies (e.g., silicon-based dies), one or more of the dies 2256 may be memory dies (e.g., high bandwidth memory), etc. In some embodiments, any of the dies 2256 may include one or more vertical TFETs, e.g., as discussed above; in some embodiments, at least some of the dies 2256 may not include any III-N diodes with n-doped wells and capping layers.

The IC package 2200 illustrated in FIG. 12 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 12, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

### Example IC Device

FIG. 13 is a cross-sectional side view of an IC device assembly 2300 that may include components having one or more IC devices implementing vertical TFETs, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing one or more vertical TFETs in accordance with any of the embodiments disclosed herein; e.g., any of the IC packages discussed below with reference to the IC device assembly 2300 may take the form of any of the embodiments of the IC package 2200 discussed above with reference to FIG. 12 (e.g., may include one or more vertical TFETs in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 13 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 13), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 11B), an IC device (e.g., the IC device of FIGS. 1-2), or any other suitable component. In particular, the IC package 2320 may include one or more vertical TFETs as described herein. Although a single IC package 2320 is shown in FIG. 13, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 13, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other Group III-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing one or more vertical TFETs as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 13 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

### Example Computing Device

FIG. 14 is a block diagram of an example computing device 2400 that may include one or more components including one or more vertical TFETs in accordance with any of the embodiments disclosed herein. For example, any suitable ones of the components of the computing device 2400 may include a die (e.g., the die 2002 (FIG. 11B)) having one or more vertical TFETs. Any one or more of the components of the computing device 2400 may include, or be included in, an IC device 2200 (FIG. 12). Any one or more of the components of the computing device 2400 may include, or be included in, an IC device assembly 2300 (FIG. 13).

A number of components are illustrated in FIG. 14 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 14, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM, nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4 K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

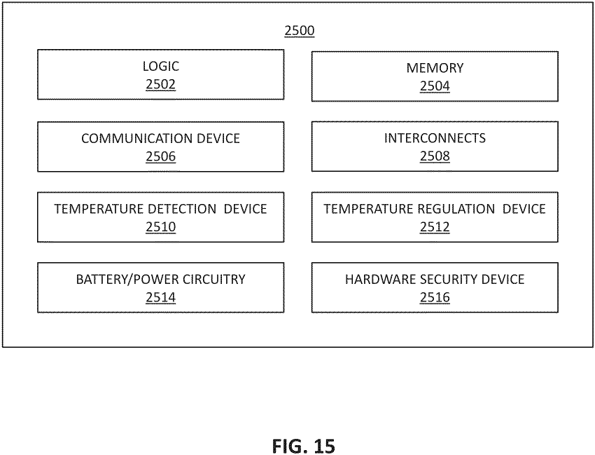

FIG. 15 is a block diagram of an example processing device 2500 that may include one or more vertical TFETs in accordance with any of the embodiments disclosed herein. For example, any suitable ones of the components of the processing device 2500 may include a die (e.g., the die 2002 (FIG. 11B)) having one or more vertical TFETs. Any one or more of the components of the processing device 2500 may include, or be included in, an IC device 2200 (FIG. 12). Any one or more of the components of the processing device 2500 may include, or be included in, an IC device assembly 2300 (FIG. 13). Any one or more of the components of the processing device 2500 may include, or be included in, a computing device 2400 (FIG. 14); for example, the processing device 2500 may be the processing device 2402 of the computing device 2400.

A number of components are illustrated in FIG. 15 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 15, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 14). In some embodiments, the memory 2504 may be a designated device configured to provide storage functionality for the components of the processing device 2500 (i.e., local), while the memory 2404 may be configured to provide system-level storage functionality for the entire computing device 2400 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access of its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m₁, m₂, ..., mₙ) in which each member mᵢ is typically smaller and faster than the next highest member mᵢ₊₁ of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 14). In some embodiments, the communication device 2506 may be a designated device configured to provide communication functionality for the components of the processing device 2500 (i.e., local), while the communication chip 2406 may be configured to provide system-level communication functionality for the entire computing device 2400 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 (FIG. 14) but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 (FIG. 14) but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 (FIG. 14). In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 (FIG. 14). In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

### Select Examples

Example 1 provides an IC device, including: a substrate; a first region, including a first semiconductor material with dopants of a first type; a second region, including a second semiconductor material with dopants of a second type, the second type different from the first type; and a channel region, including a third semiconductor material, where: the channel region is between the first region and the second region, the first region is between the channel region and the substrate, one of the first region and the second region is a source region of a transistor, and another one of the first region and the second region is a drain region of the transistor.

Example 2 provides the IC device according to example 1, further including: a gate wrapping around at least a portion of the channel region, where a longitudinal axis of the gate is orthogonal to the substrate.

Example 3 provides the IC device according to example 2, where the gate includes: a gate insulator wrapping around at least a portion of the channel region; and a gate electrode wrapping around at least a portion of the gate insulator.

Example 4 provides the IC device according to any of the preceding examples, where the dopants of the first type are n-type dopants and the dopants of the second type are p-type dopants.

Example 5 provides the IC device according to any of the preceding examples, where the first semiconductor material is different from the second semiconductor material or the third semiconductor material.

Example 6 provides the IC device according to any of the preceding examples, where the first semiconductor material, the second semiconductor material, and the third semiconductor material are the same.

Example 7 provides the IC device according to any of the preceding examples, where the first region incudes a first crystal structure, the second region includes a second crystal structure, and a crystal orientation of the first crystal structure is unaligned with a crystal of the second crystal structure.

Example 8 provides the IC device according to any of the preceding examples, where the channel region includes a first crystal structure, the second region includes a second crystal structure, and a crystal orientation of the first crystal structure is unaligned with a crystal of the second crystal structure.

Example 9 provides the IC device according to any of the preceding examples, where a portion of the second region is wrapped around by the channel region.

Example 10 provides the IC device according to any of the preceding examples, where a surface of the first region is connected with a surface of the channel region, and an area of the surface of the first region is smaller than an area of the surface of the channel region.

Example 11 provides a method for forming an IC device, the method including: providing a first region over a substrate, the first region including a first semiconductor material with dopants of a first type; providing a channel region over the first region; providing a second region at least partially over the channel region, the second region including a second semiconductor material with dopants of a second type, where the second type is different from the first type; providing a gate insulator that wraps around at least a portion of the channel region; and providing a gate electrode that wraps around at least a portion of the gate insulator.

Example 12 provides the method according to example 11, where providing the channel region over the first region includes: providing the channel region over a substrate to form a combined structure; and bonding the combined structure with the first region; and removing the substrate.

Example 13 provides the method according to example 11 or 12, where providing the channel region over the first region includes: providing a precursor of a semiconductor material of the channel region onto a surface of the first region.

Example 14 provides the method according to any one of examples 11-13, where providing the second region at least partially over the channel region includes: providing a mixture of a precursor of the second semiconductor material and the dopants of the second type onto a surface of the channel region.

Example 15 provides the method according to example 14, where providing the second region at least partially over the channel region further includes: providing a guiding pattern at a surface of the channel region, the guiding pattern including an opening in the channel region, where providing the mixture of the precursor of the second semiconductor material and the dopants of the second type onto the surface of the channel region includes providing the mixture into the opening.

Example 16 provides the method according to example 15, where providing the mixture into the opening includes: providing a guiding material into the opening, where the guiding material includes oriented grains; and providing the mixture onto the guiding material.

Example 17 provides the method according to any one of examples 11-16, where providing the channel region over the first region includes: providing a guiding material onto a surface of the first region, where the guiding material includes oriented grains; and providing the semiconductor material onto the guiding material.

Example 18 provides a method for forming an IC device, including: providing an opening in an insulator over a substrate; providing a first layer in the opening, the first layer including a first semiconductor material; doping the first layer with dopants of a first type; providing a second layer over a first layer, the second layer including a second semiconductor material; providing a third layer over the second layer, the third layer including a third semiconductor material; and doping the third layer with dopants of a second type, where the second type is different from the first type, and where the first layer and at least a portion of the second layer are wrapped around by the insulator.

Example 19 provides the method according to example 18, further including: forming an electrode that wraps around at least a portion of the insulator.

Example 20 provides the method according to example 18, where providing the third layer over the second layer and doping the third layer with the dopants of the second type include spraying a mixture of a precursor of the third semiconductor material and the dopants of the second type onto a surface of the second layer.

Example 21 provides an IC package, including the IC device according to any one of examples 1-10; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device according to any one of examples 1-10 may include, or be a part of, at least one of a memory device, a computing device, a wearable device, a handheld electronic device, and a wireless communications device.

Example 24 provides an electronic device, including a carrier substrate; and one or more of the IC devices according to any one of examples 1-10 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides the method according to any one of examples 11-20, further including processes for forming the IC device according to any one of examples 1-10.

Example 35 provides the method according to any one of examples 11-20, further including processes for forming the IC package according to any one of the examples 21-23.

Example 36 provides the method according to any one of examples 11-20, further including processes for forming the electronic device according to any one of the examples 24-31.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a substrate;
a first region, comprising a first semiconductor material with dopants of a first type;
a second region, comprising a second semiconductor material with dopants of a second type, the second type different from the first type; and
a channel region, comprising a third semiconductor material, wherein:
the channel region is between the first region and the second region,
the first region is between the channel region and the substrate,
one of the first region and the second region is a source region of a transistor, and
another one of the first region and the second region is a drain region of the transistor.

2. The IC device according to claim 1, further comprising:
a gate wrapping around at least a portion of the channel region, wherein a longitudinal axis of the gate is orthogonal to the substrate.

3. The IC device according to claim 2, wherein the gate comprises:
a gate insulator wrapping around at least a portion of the channel region; and
a gate electrode wrapping around at least a portion of the gate insulator.

4. The IC device according to claim 1, wherein the dopants of the first type are n-type dopants and the dopants of the second type are p-type dopants.

5. The IC device according to claim 1, wherein the first semiconductor material is different from the second semiconductor material or the third semiconductor material.

6. The IC device according to claim 1, wherein the first semiconductor material, the second semiconductor material, and the third semiconductor material are the same.

7. The IC device according to claim 1, wherein the first region incudes a first crystal structure, the second region includes a second crystal structure, and a crystal orientation of the first crystal structure is unaligned with a crystal of the second crystal structure.

8. The IC device according to claim 1, wherein the channel region includes a first crystal structure, the second region includes a second crystal structure, and a crystal orientation of the first crystal structure is unaligned with a crystal of the second crystal structure.

9. The IC device according to claim 1, wherein a portion of the second region is wrapped around by the channel region.

10. The IC device according to claim 1, wherein a surface of the first region is connected with a surface of the channel region, and an area of the surface of the first region is smaller than an area of the surface of the channel region.

11. A method for forming an integrated circuit (IC) device, the method comprising:
providing a first region over a substrate, the first region including a first semiconductor material with dopants of a first type;
providing a channel region over the first region;
providing a second region at least partially over the channel region, the second region including a second semiconductor material with dopants of a second type, wherein the second type is different from the first type;
providing a gate insulator that wraps around at least a portion of the channel region; and
providing a gate electrode that wraps around at least a portion of the gate insulator.

12. The method according to claim 11, wherein providing the channel region over the first region comprises:
providing the channel region over a substrate to form a combined structure;
bonding the combined structure with the first region; and
removing the substrate.

13. The method according to claim 11, wherein providing the channel region over the first region comprises:
providing a precursor of a semiconductor material of the channel region onto a surface of the first region.

14. The method according to claim 11, wherein providing the second region at least partially over the channel region comprises:
providing a mixture of a precursor of the second semiconductor material and the dopants of the second type onto a surface of the channel region.

15. The method according to claim 14, wherein providing the second region at least partially over the channel region further comprises:
providing a guiding pattern at a surface of the channel region, the guiding pattern comprising an opening in the channel region,
wherein providing the mixture of the precursor of the second semiconductor material and the dopants of the second type onto the surface of the channel region comprises providing the mixture into the opening.

16. The method according to claim 15, wherein providing the mixture into the opening comprises:
providing a guiding material into the opening, wherein the guiding material includes oriented grains; and
providing the mixture onto the guiding material.

17. The method according to claim 11, wherein providing the channel region over the first region comprises:
providing a guiding material onto a surface of the first region, wherein the guiding material includes oriented grains; and
providing the semiconductor material onto the guiding material.

18. A method for forming an integrated circuit (IC) device, comprising:
providing an opening in an insulator over a substrate;
providing a first layer in the opening, the first layer comprising a first semiconductor material;
doping the first layer with dopants of a first type;
providing a second layer over a first layer, the second layer comprising a second semiconductor material;
providing a third layer over the second layer, the third layer comprising a third semiconductor material; and
doping the third layer with dopants of a second type,
wherein the second type is different from the first type, and wherein the first layer and at least a portion of the second layer are wrapped around by the insulator.

19. The method according to claim 18, further comprising:
forming an electrode that wraps around at least a portion of the insulator.

20. The method according to claim 18, wherein providing the third layer over the second layer and doping the third layer with the dopants of the second type comprise spraying a mixture of a precursor of the third semiconductor material and the dopants of the second type onto a surface of the second layer.
